(19) United States
(12) Patent Application Publication
(10) Pub. No.: US 2026/0282674 A1
(43) Pub. Date: Sep. 17, 2026

(54) Display Panel, Display Apparatus and Tiled Display Apparatus

(71) Applicants: BOE MLED Technology Co., Ltd., Beijing (CN); BOE TECHNOLOGY GROUP CO., LTD., Beijing (CN); BEIJING BOE TECHNOLOGY DEVELOPMENT CO., LTD., Beijing (CN)

(72) Inventors: Mingming Jia, Beijing (CN); Jing Wang, Beijing (CN); Shanshan Feng, Beijing (CN); Mengqing Liu, Beijing (CN); Huaimin Wang, Beijing (CN); Lili Wang, Beijing (CN); Jingping Zhao, Beijing (CN); Chao Liu, Beijing (CN); Yuyang Li, Beijing (CN); Ming Zhai, Beijing (CN); Qi Qi, Beijing (CN)

(21) Appl. No.: 18/993,805

(22) PCT Filed: Feb. 29, 2024
(86) PCT No.: PCT/CN2024/079470

§ 371 Date: Jan. 13, 2025

(51) Int. Cl. H10K 59/131; H10K 59/95

(52) U.S. Cl. CPC H10K 59/131; H10K 59/95

(57) ABSTRACT

A display panel, a display apparatus and a tiled display apparatus. The display panel includes a substrate and a plurality of connection leads. The substrate includes a first surface and a second surface that are oppositely disposed, and at least one side surface connecting the first surface and the second surface. At least one of the at least one side surface is a selected side surface. Each connection lead in the plurality of connection leads extends from the first surface to the second surface through the selected side surface. The plurality of connection leads include a first connection lead and a second connection lead, and the first connection lead and the second connection lead are adjacent to each other and disposed in different layers in a direction perpendicular to the surface of the substrate. The display panel is used to display images.

### CROSS-REFERENCE TO RELATED APPLICATION

This application is the United States national phase of International Patent Application No. PCT/CN2024/079470, filed Feb. 29, 2024, the disclosure of which is hereby incorporated by reference in its entirety.

### BACKGROUND OF THE INVENTION

### Field of the Invention

The present disclosure relates to the field of display technologies, and in particular, to a display panel, a display apparatus and a tiled display apparatus.

### Description of Related Art

Micro light-emitting diodes (Micro LEDs) or mini light-emitting diodes (Mini LEDs) are used as pixels of display panels, which has attracted widespread attention and research. At present, large-size display apparatuses cannot be fabricated at one time due to the problem of the mass transfer yield of Micro LED display panels and Mini LED display panels. A large-size tiled display apparatus is usually fabricated by tiling small-size display apparatuses.

### SUMMARY OF THE INVENTION

In an aspect, a display panel is provided. The display panel includes a substrate and a plurality of connection leads.

The substrate includes a first surface and a second surface that are oppositely disposed, and at least one side surface connecting the first surface and the second surface. At least one of the at least one side surface is a selected side surface.

Each connection lead in the plurality of connection leads extends from the first surface to the second surface through the selected side surface.

The plurality of connection leads include a first connection lead and a second connection lead, and the first connection lead and the second connection lead are adjacent to each other and disposed in different layers in a direction perpendicular to the surface of the substrate.

In some embodiments, orthogonal projections of the first connection lead and the second connection lead on the substrate at least partially overlap with each other.

In some embodiments, line widths of the first connection lead and the second connection lead are different.

In some embodiments, signals transmitted by the first connection lead are different from signals transmitted by the second connection lead.

In some embodiments, one of the first connection lead and the second connection lead is in contact with the surface of the substrate.

In some embodiments, the display panel further includes a plurality of front electrodes and a plurality of back electrodes.

The plurality of front electrodes are disposed on a side of the first surface of the substrate. The plurality of front electrodes include a first electrode and a second electrode, and the first electrode and the second electrode are disposed adjacent to each other.

The plurality of back electrodes are disposed on a side of the second surface of the substrate. The plurality of back electrodes include a third electrode and a fourth electrode, and the third electrode and the fourth electrode are disposed adjacent to each other.

The first connection lead connects the first electrode and the third electrode. The second connection lead connects the second electrode and the fourth electrode.

Orthogonal projections of the first electrode and the third electrode on the second surface at least partially overlap with each other, and orthogonal projections of the second electrode and the fourth electrode on the second surface at least partially overlap with each other.

In some embodiments, the first electrode is disposed in a same layer as the second electrode, and/or, the third electrode is disposed in a same layer as the fourth electrode.

In some embodiments, one of the first connection lead and the second connection lead is directly connected to at least one of the plurality of front electrodes and at least one of the plurality of back electrodes, and another of the first connection lead and the second connection lead is connected to one or more of the plurality of front electrodes and one or more of the plurality of back electrodes through a via hole.

In some embodiments, the first electrode and the second electrode are disposed in different layers, and the first electrode is closer to the first surface than the second electrode.

And/or, the third electrode and the fourth electrode are disposed in different layers, and the third electrode is closer to the second surface than the fourth electrode.

In some embodiments, the first connection lead is closer to the substrate than the second connection lead.

In some embodiments, an orthogonal projection of the first electrode on the first surface at least partially overlaps with an orthogonal projection of the second electrode on the first surface.

And/or, the orthogonal projection of the third electrode on the second surface at least partially overlaps with the orthogonal projection of the fourth electrode on the second surface.

In some embodiments, the display panel further includes a plurality of pixel units located on the first surface. The plurality of pixel units include two pixel units that are adjacent to each other in a first direction and both proximate to the selected side surface, and the first electrode and the second electrode are disposed between the two pixel units.

In some embodiments, the display panel further includes a plurality of pixel units located on the first surface. The plurality of pixel units include two pixel units that are adjacent to each other in a first direction and both proximate to the selected side surface.

The first connection lead and the second connection lead are disposed between the two pixel units.

In some embodiments, the display panel further includes a plurality of pixel units located on the first surface. The plurality of pixel units include two pixel units that are adjacent to each other in a first direction and both proximate to the selected side surface.

The first electrode and the second electrode at least partially overlap with the two pixel units in a second direction. The second direction is perpendicular to the first direction.

In some embodiments, the display panel further includes a first insulating layer. The first insulating layer is located between the first connection lead and the second connection lead.

In some embodiments, the display panel further includes at least one depressed region located on at least the selected side surface of the substrate.

An orthogonal projection of one of the first connection lead and the second connection lead that is closer to the substrate on the selected side surface is located within the depressed region.

In some embodiments, a ratio of a dimension of the depressed region in a first direction to a dimension of the first connection lead in the first direction is within a range of 1 to 2, inclusive.

In some embodiments, the display panel further includes a protective layer. The protective layer covers at least the second connection lead, and at least one of the plurality of front electrodes and at least one of the plurality of back electrodes that are connected to the second connection lead.

In another aspect, a display apparatus is provided. The display apparatus includes the display panel as described in any one of the above embodiments and a circuit board. The circuit board is electrically connected to the display panel, and the circuit board is configured to drive the display panel to display images.

In yet another aspect, a tiled display apparatus is provided. The tiled display apparatus includes a plurality of display panels each described in any one of the above embodiments and at least one circuit board.

The plurality of the display panels are tiled together, and each of the at least one circuit board is electrically connected to at least one of the plurality of display panels.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to these accompanying drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a diagram showing a structure of a tiled display apparatus, in accordance with some embodiments;

FIG. 2 is a diagram showing a structure of a display apparatus, in accordance with some embodiments;

FIG. 3 is a sectional view of the display panel in FIG. 2 taken along the section line B-B;

FIG. 4 is a diagram showing a structure of a partial region of a display panel, in accordance with some embodiments;

FIG. 5A is a diagram showing another structure of a partial region of a display panel, in accordance with some embodiments;

FIG. 5B is a diagram showing yet another structure of a partial region of a display panel, in accordance with some embodiments;

FIG. 6 is a diagram showing yet another structure of a partial region of a display panel, in accordance with some embodiments;

FIG. 7 is a diagram showing a structure of a display panel, in accordance with some embodiments;

FIG. 8A is a diagram showing yet another structure of a partial region of a display panel, in accordance with some embodiments;

FIG. 8B is a diagram showing yet another structure of a partial region of a display panel, in accordance with some embodiments;

FIG. 9A is a diagram showing yet another structure of a partial region of a display panel, in accordance with some embodiments;

FIG. 9B is a diagram showing yet another structure of a partial region of a display panel, in accordance with some embodiments;

FIG. 9C is a diagram showing yet another structure of a partial region of a display panel, in accordance with some embodiments;

FIG. 9D is a diagram showing yet another structure of a partial region of a display panel, in accordance with some embodiments;

FIG. 10A is a diagram showing yet another structure of a partial region of a display panel, in accordance with some embodiments;

FIG. 10B is a diagram showing yet another structure of a partial region of a display panel, in accordance with some embodiments;

FIG. 10C is a diagram showing yet another structure of a partial region of a display panel, in accordance with some embodiments;

FIG. 10D is a diagram showing yet another structure of a partial region of a display panel, in accordance with some embodiments;

FIG. 11A is a diagram showing yet another structure of a partial region of a display panel, in accordance with some embodiments;

FIG. 11B is a diagram showing yet another structure of a partial region of a display panel, in accordance with some embodiments;

FIG. 12A is a diagram showing yet another structure of a partial region of a display panel, in accordance with some embodiments;

FIG. 12B is a diagram showing yet another structure of a partial region of a display panel, in accordance with some embodiments;

FIG. 13A is a diagram showing yet another structure of a partial region of a display panel, in accordance with some embodiments;

FIG. 13B is a diagram showing yet another structure of a partial region of a display panel, in accordance with some embodiments;

FIG. 13C is a sectional view of the display panel in FIG. 12A taken along the section line H-H;

FIG. 13D is another sectional view of the display panel in FIG. 12A taken along the section line H-H;

FIG. 13E is yet another sectional view of the display panel in FIG. 12A taken along the section line H-H;

FIG. 14A is a diagram showing yet another structure of a partial region of a display panel, in accordance with some embodiments;

FIG. 14B is a diagram showing yet another structure of a partial region of a display panel, in accordance with some embodiments;

FIG. 15A is a diagram showing yet another structure of a partial region of a display panel, in accordance with some embodiments;

FIG. 15B is a diagram showing yet another structure of a partial region of a display panel, in accordance with some embodiments;

FIG. 15C is a diagram showing yet another structure of a partial region of a display panel, in accordance with some embodiments;

FIG. 16 is a sectional view of the display panel in FIG. 15A taken along the section line G-G;

FIG. 17 is another sectional view of the display panel in FIG. 15A taken along the section line G-G;

FIG. 18 is a sectional view of a partial region of a display panel, in accordance with some embodiments;

FIG. 19A is a diagram showing yet another structure of a partial region of a display panel, in accordance with some embodiments;

FIG. 19B is a diagram showing yet another structure of a partial region of a display panel, in accordance with some embodiments;

FIG. 20A is a diagram showing yet another structure of a partial region of a display panel, in accordance with some embodiments; and

FIG. 20B is a diagram showing yet another structure of a partial region of a display panel, in accordance with some embodiments.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the expressions “coupled”, “connected”, and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The term “coupled”, for example, indicates that two or more components are in direct physical or electrical contact with each other. The term “coupled” or “communicatively coupled” may also mean that two or more components are not in direct contact with each other but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

As used herein, the term “if” is optionally construed as “when” or “in a case where” or “in response to determining that” or “in response to detecting”, depending on the context. Similarly, depending on the context, the phrase “if it is determined that” or “if [a stated condition or event] is detected” is optionally construed as “in a case where it is determined that”, “in response to determining that”, “in a case where [the stated condition or event] is detected” or “in response to detecting [the stated condition or event]”.

The phrase “applicable to” or “configured to” used herein means an open and inclusive expression, which does not exclude devices that are applicable to or configured to perform additional tasks or steps.

In addition, the phase “based on” as used herein is meant to be open and inclusive, since a process, a step, a calculation or other action that is “based on” one or more of stated conditions or values may, in practice, be based on additional conditions or values beyond those stated.

The term “about”, “substantially”, and “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular”, or “equal” as used herein includes a stated condition and a condition similar to the stated condition. A range of the similar condition is within an acceptable range of deviation, and the acceptable range of deviation is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Thus, variations in shape with respect to the accompanying drawings due to, for example, manufacturing technologies and/or tolerances may be envisaged. And the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in devices, and are not intended to limit the scope of the exemplary embodiments.

For convenience of the following description, an XYZ coordinate system is established. The third direction Z is a thickness direction of a tiled display apparatus or a display apparatus, the XY plane is perpendicular to the Z direction, and the first direction X intersects the second direction Y. For example, the first direction X and the second direction Y are perpendicular to each other.

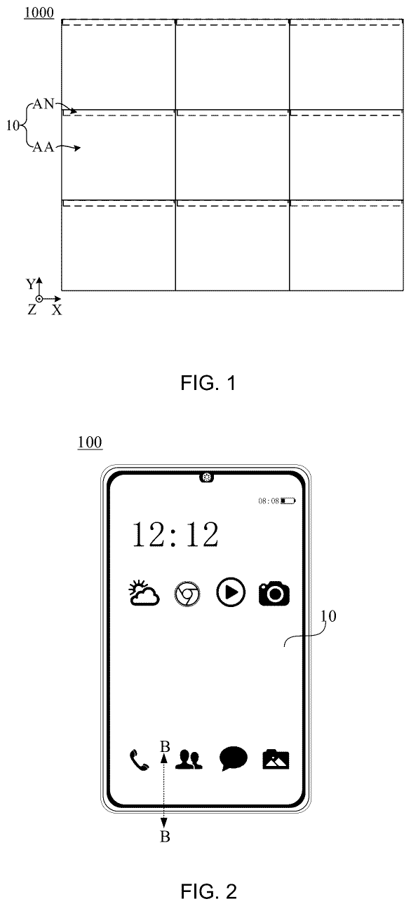

As shown in FIG. 1, a tiled display apparatus 1000 is provided in some embodiments of the present disclosure. The tiled display apparatus 1000 includes a plurality of display panels 10 tiled together and at least one circuit board (not shown in the drawing). Each circuit board is electrically connected to at least one display panel 10 and used to control the display panel 10 to emit light, so as achieve the display function of the display panel 10.

Product reliability may be improved and transportation costs and maintenance costs may be reduced by tiling the plurality of display panels 10 to form a large-sized tiled display apparatus 1000.

For example, the number of circuit boards in the tiled display apparatus 1000 may be one, and the plurality of display panels 10 are all connected to a same circuit board.

The number of circuit boards may also be multiple. For example, each display panel 10 in the plurality of display panels 10 is connected to one circuit board. That is to say, the display panels 10 and the circuit boards are connected in one-to-one correspondence. For another example, the plurality of display panels 10 are divided into a plurality of groups, and each group of display panels 10 is connected to one circuit board. The number of display panels 10 in each group of display panels 10 may be same or different.

For example, the circuit board includes but is not limited to a printed circuit board (PCB) and a flexible printed circuit board (FPC).

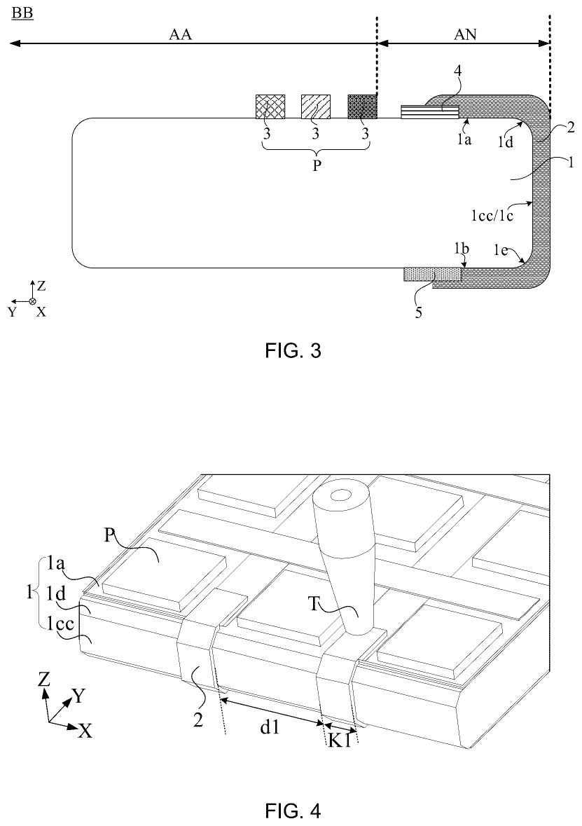

As shown in FIG. 2, a display apparatus 100 is further provided in some embodiments of the disclosure. The display apparatus 100 may be an independent display apparatus or may be used for tiling to form the tiled display apparatus 1000.

For example, the display apparatus 100 may be any product or component having display functions such as a television, a monitor, a notebook computer, a tablet computer, a mobile phone or a navigator. FIG. 2 illustrates an example in which the display apparatus 100 is a mobile phone.

For example, the display apparatus 100 may be a micro light-emitting diode (Micro LED) display apparatus and a mini light-emitting diode (Mini LED) display apparatus.

The display apparatus 100 may also be an electroluminescent display apparatus or a photoluminescence display apparatus. In a case where the display apparatus 100 is the electroluminescent display apparatus, the electroluminescent display apparatus may be an organic light-emitting diode (OLED) display apparatus or a quantum dot light-emitting diodes (QLED) display apparatus. In a case where the display apparatus 100 is the photoluminescent display apparatus, the photoluminescent display apparatus may be a quantum dot photoluminescent display apparatus.

With continued reference to FIG. 2, the display apparatus 100 includes a display panel 10 and a circuit board (not shown in the drawing). The circuit board is electrically connected to the display panel 10 and configured to drive the display panel 10 to display images.

The display panel 10 will be described in detail below.

The display panel 10 may be a Micro LED display panel or a Mini LED display panel, or may also be an OLED display panel.

For example, in a case where the display panel 10 is the Micro LED display panel or the Mini LED display panel, the Micro LED display panel or the Mini LED display panel includes an array substrate and micro light-emitting diodes or mini light-emitting diodes located on the array substrate.

For another example, in a case where the display panel 10 is the OLED display panel, the OLED display panel includes an array substrate and a pixel definition layer located on the array substrate. An anode, a hole injection layer, a hole transport layer, a light-emitting layer, an electron transport layer, an electron injection layer and a cathode are sequentially disposed within a pixel definition region of the pixel definition layer.

Some embodiments of the present disclosure are exemplarily described below by considering an example in which the display panel 10 is the Micro LED display panel or the Mini LED display panel. However, the embodiments of the present disclosure include but are not limited to this, and any other display panel may also be considered as long as a same technical concept is applied.

For example, the display panel 10 may be a rectangular structure, a circular structure, or other shapes with corners, which is not specifically limited in the present disclosure.

It will be noted that, the phrase “rectangular structure” means that a border of the display panel 10 is in a shape of a rectangle as a whole, but is not limited to a standard rectangle. That is to say, the term “rectangle” herein includes not only the standard rectangle but also a shape similar to the rectangle in consideration of process conditions. For example, the long sides and short sides of the rectangle are curved at each intersecting position (i.e., corners). That is to say, the corners are smooth, so that the border of the display panel 10 is in a shape of a rectangle with rounded corners in a plan view.

Some embodiments of the present disclosure are exemplarily described below by considering an example in which the display panel 10 is a rectangular structure. However, the embodiments of the present disclosure include but are not limited to this, and the shape of the display panel 10 may also be considered as any other shape.

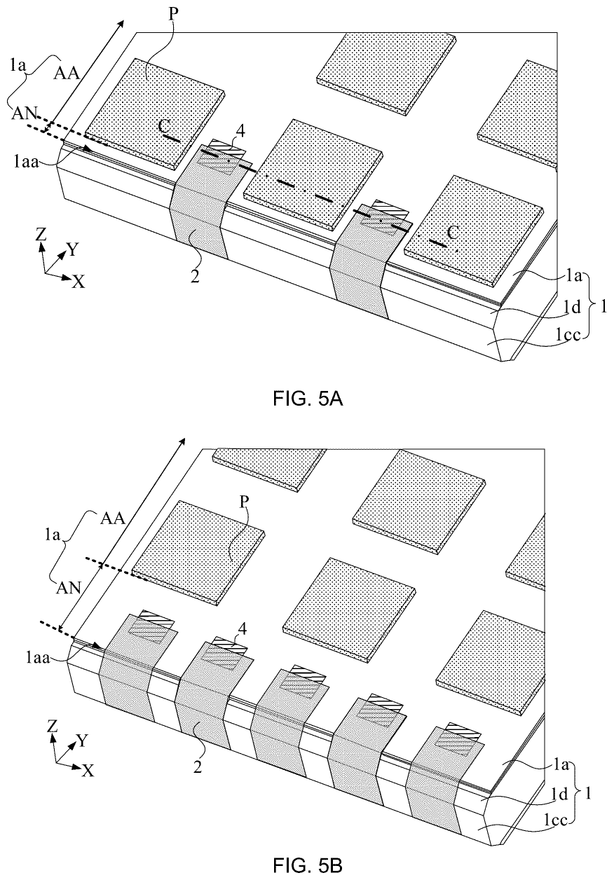

In some embodiments, as shown in FIG. 3, FIG. 3 is a sectional view of the display panel 10 in FIG. 2 taken along the section line B-B. The display panel 10 has a display region AA for displaying images and a peripheral region AN located on at least one side of the display region AA.

For example, the peripheral region AN is located on a side of the display region AA.

For another example, the peripheral region AN is located on two opposite sides of the display region AA.

For yet another example, the peripheral region AN surrounds the display region AA.

It will be noted that the specific arrangement of the peripheral region AN is related to the specific design of the display panel 10 and may be designed according to actual requirements. This is only used as an example, but not a limitation to the present disclosure.

In some embodiments, as shown in FIG. 3, a plurality of pixel units P are disposed within the display region AA of the display panel 10, and each pixel unit P includes sub-pixels 3 of at least three colors, and the sub-pixel 3 is a minimum pixel unit within the display region AA.

The “each pixel unit P includes sub-pixels 3 of at least three colors” means that each pixel unit P may include three, four or more sub-pixels 3, and the plurality of sub-pixels 3 included by each pixel unit P may be a row, a column or a group of sub-pixels 3. A group of sub-pixels 3 may be a plurality of sub-pixels 3 adjacent to each other, and the plurality of sub-pixels 3 adjacent to each other may be arranged in a row, a column, a shape of a capital letter L, a rectangular shape or a rhombic shape, etc. Meanwhile, light-emitting areas of the plurality of sub-pixels 3 included by each pixel unit P may be same or different. The above description is only an example and does not limit the present disclosure, detail may be designed adaptively according to actual requirements.

In some examples, the plurality of sub-pixels 3 emit light of a same color, and the display panel 10 may further include a color film layer disposed on light-exit sides of the plurality of sub-pixels 3.

For example, the plurality of sub-pixels 3 all emit light such as white light, red light, green light or blue light. In this case, light emitted by the sub-pixel 3 remains a same color light and exits after passing through the color film layer, or light emitted by the sub-pixel 3 is converted into light of other color and exits after passing through the color film layer. As a result, in a case where the plurality of sub-pixels 3 emit light of a same color, the display panel 10 may achieve output of light of multiple colors.

In some other examples, the plurality of sub-pixels 3 emit light of different colors. For example, the plurality of sub-pixels 3 include a red light sub-pixel emitting red light, a green light sub-pixel emitting green light, and a blue light sub-pixel emitting blue light, thereby achieving multi-color light output of the display panel 10.

For example, the pixel unit P includes a driving assembly and a light-emitting assembly. For example, the driving assembly may include a thin film transistor, and the light-emitting assembly may include a Mini LED or a Micro LED.

For example, the plurality of pixel units P are arranged in a plurality of rows and columns. That is to say, the plurality of pixel units P are arranged in an array in the first direction X and the second direction Y.

In some embodiments, the peripheral region AN of the display panel 10 may be used to arrange peripheral circuits and signal lines of the display region AA.

In some embodiments, with continued reference to FIG. 3, the display panel 10 further includes a substrate 1. The substrate 1 includes a first surface 1a and a second surface 1b that are oppositely disposed, and at least one side surface 1c connecting the first surface 1a and the second surface 1b. The pixel units P mentioned above are disposed on the first surface 1a of the substrate 1.

For example, the substrate 1 may be made of a rigid material. For example, the material of the substrate 1 includes but is not limited to glass, quartz, or plastic. The substrate 1 may also be made of a flexible material. For example, the material of the substrate 1 includes but is not limited to FPC or polyimide film (PI film).

It will be noted that the selected material of the substrate 1 is related to the specific design of the display panel 10 and may be selected according to actual requirements. This is only used as an example, but not a limitation to the present disclosure.

For example, as shown in FIG. 3, the side surface 1c is perpendicular or substantially perpendicular to the first surface 1a and the second surface 1b.

In some embodiments, with continued reference to FIG. 3, the substrate 1 further includes a first chamfered surface 1d and a second chamfered surface 1e. The first chamfered surface 1d connects the first surface 1a of the substrate 1 and the side surface 1c of the substrate 1, and the second chamfered surface 1e connects the second surface 1b of the substrate 1 and the side surface 1c of the substrate 1.

For example, the first chamfered surface 1d and the second chamfered surface 1e may be set as cambered surfaces or inclined surfaces. FIG. 3 illustrates an example in which the first chamfered surface 1d and the second chamfered surface 1e may be set as only cambered surfaces.

For example, in a case where the first chamfered surface 1d of the substrate 1 is a cambered surface, the first surface 1a may be smoothly transitioned from the first chamfered surface 1d to the side surface 1c, or the side surface 1c may be smoothly transitioned from the first chamfered surface 1d to the first surface 1a.

Similarly, in a case where the second chamfered surface 1e of the substrate 1 is also a cambered surface, the second surface 1b may be smoothly transitioned from the second chamfered surface 1e to the side surface 1c, or the side surface 1c may be smoothly transitioned from the second chamfered surface 1e to the second surface 1b.

For another example, in a case where the first chamfered surface 1d of the substrate 1 is an inclined surface, an included angle between the first chamfered surface 1d and the first surface 1a of the substrate 1 and an included angle between the first chamfered surface 1d and the side surface 1c of the substrate 1 are both obtuse angles. The first surface 1a may be relatively smoothly transitioned from the first chamfered surface 1d to the side surface 1c, or the side surface 1c may be relatively smoothly transitioned from the first chamfered surface 1d to the first surface 1a.

Similarly, in a case where the second chamfered surface 1e of the substrate 1 is also an inclined surface, the second surface 1b may be relatively smoothly transitioned from the second chamfered surface 1e to the side surface 1c, or the side surface 1c may be relatively smoothly transitioned from the second chamfered surface 1e to the second surface 1b.

Some embodiments of the present disclosure are exemplarily described below by considering an example in which the substrate 1 includes the first surface 1a, the second surface 1b, the side surface 1c, the first chamfered surface 1d and the second chamfered surface 1e.

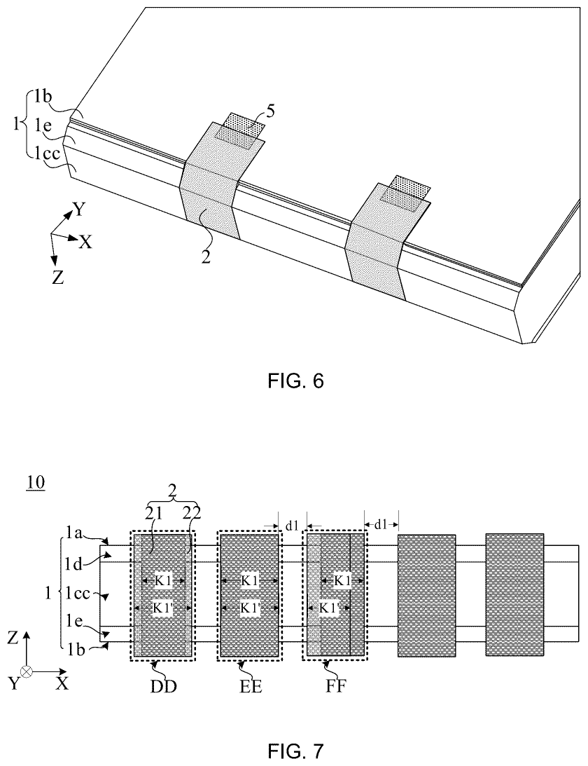

In some embodiments, with continued reference to FIGS. 3 and 4, the display panel 10 further includes a plurality of connection leads 2. The plurality of connection leads 2 are arranged at intervals in the first direction X. On the first surface 1a of the substrate 1, the first direction X is perpendicular to an extending direction (the second direction Y) of the connection leads 2.

Each connection lead 2 in the plurality of connection leads 2 extends from the first surface 1a of the substrate 1 to the second surface 1b of the substrate 1 through the side surface 1c of the substrate 1. For the convenience of description, the side surface 1c where the connection leads 2 are located is collectively referred to as a selected side surface 1cc hereinafter.

It will be noted that, in a case where the substrate 1 includes a plurality of side surfaces 1c, the present disclosure does not limit the structures of other side surfaces 1c (i.e., side surfaces 1c other than the selected side surface 1cc ) in the plurality of side surfaces 1c. For example, in a case where the display panel 10 is a rectangular structure, the display panel 10 has four side surfaces 1c. For example, the four side surfaces 1c of the substrate 1 may all be the selected side surfaces 1cc. For another example, as shown in FIG. 3, one side surface 1c in the four side surfaces 1c of the substrate 1 is the selected side surface 1cc, and the structures of the other three side surfaces 1c are not limited.

With continued reference to FIG. 3, it may be understood that in a case where the substrate 1 has the first chamfered surface 1d and the second chamfered surface 1e, each of the plurality of connection leads 2 extends from the first surface 1a of the substrate 1 to the second surface 1b of the substrate 1 through the first chamfered surface 1d of the substrate 1, the selected side surface 1cc of the substrate 1 and the second chamfered surface 1e of the substrate 1 in sequence. When the plurality of connection leads 2 pass through the first chamfered surface 1d, the first surface 1a of the substrate 1 may be smoothly transitioned from the first chamfered surface 1d to the selected side surface 1cc, or the selected side surface 1cc may be smoothly transitioned from the first chamfered surface 1d to the first surface 1a. Therefore, compared with a case where the first surface 1a is directly connected to the selected side surface 1cc (in this case, an included angle between the first surface 1a and the selected side surface 1cc is 90°), in the embodiments of the present disclosure, each of the plurality of connection leads 2 is subjected to less stress at a corner (i.e., the first chamfered surface 1d) between the first surface 1a and the selected side surface 1cc, thereby reducing the problem of lead breakage caused by excessive stress concentration. In this way, the plurality of connection leads 2 are difficult to break at the corner (i.e., the first chamfered surface 1d) between the first surface 1a and the selected side surface 1cc, thereby ensuring that the plurality of connection leads 2 may stably connect the first surface 1a and second surface 1b of the substrate 1 that are oppositely disposed, and improving the stability of the display panel 10.

Similarly, when the plurality of connection leads 2 pass through the second chamfered surface 1e, each of the plurality of connection leads 2 is subjected to small stress at a corner (i.e., the second chamfered surface 1e) between the second surface 1b and the selected side surface 1cc, thereby reducing the problem of lead breakage caused by excessive stress concentration. In this way, the plurality of connection leads 2 are difficult to break at the corner (i.e., the second chamfered surface 1e) between the second surface 1b and the selected side surface 1cc, thereby ensuring that the plurality of connection leads 2 may effectively connect the first surface 1a and second surface 1b of the substrate 1 that are oppositely disposed, and further improving the reliability of the display panel 10.

In some embodiments, the connection leads 2 may be fabricated by patterning process after coating process, or may also be directly fabricated by a printing process.

For example, the connection leads 2 are fabricated by the printing process as follows: a conductive paste is disposed on the first surface 1a, the selected side surface 1cc and the second surface 1b of the substrate 1 (in a case where the substrate 1 includes the first chamfered surface 1d and the second chamfered surface 1e, the conductive paste is also required to be disposed on the first chamfered surface 1d and the second chamfered surface 1e of the substrate 1), and then the conductive paste is cured by laser light or heating, so as to form the connection leads 2.

The printing process may include, for example, screen printing, pad printing, transfer printing and printing.

In a case where the printing process includes the printing, the printing process may be a three-dimensional printing process. With continued reference to FIG. 4, the three-dimensional printing process uses a printing needle T with a certain caliber to squeeze the conductive paste in the needle tube to a specific position on the substrate 1 by using air pressure. A connection leads 2 are formed after the conductive paste is cured.

The conductive paste may be, for example, silver paste. The silver paste may include silver powder and resin. The silver powder melts at high temperature, so that the silver powder and resin are fused and connected with each other, thereby achieving the conductive effect.

In some embodiments, with continued reference to FIG. 3, the display panel 10 further includes a plurality of front electrodes 4 and a plurality of back electrodes 5. The plurality of front electrodes 4 are located on the first surface 1a of the substrate 1, and the plurality of back electrodes 5 are located on the second surface 1b of the substrate 1.

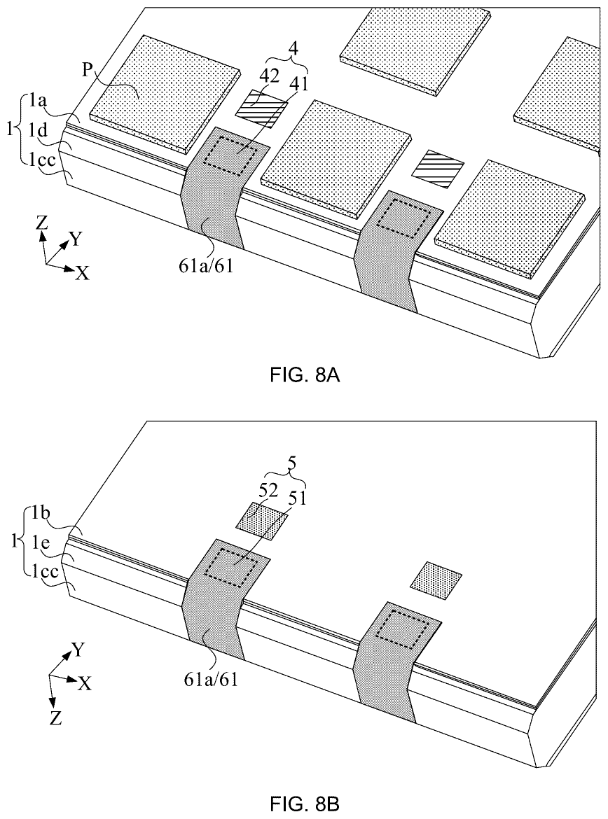

For example, as shown in FIG. 5A, FIG. 5A is a diagram showing a structure of a partial region of the display panel 10, in accordance with some embodiments of the present disclosure. The plurality of front electrodes 4 are arranged at intervals in the first direction X. The plurality of front electrodes 4 may be disposed within the display region AA of the display panel 10. With a boundary of the first surface 1a of the substrate 1 proximate to the selected side surface 1cc as a first boundary 1aa, in a row of pixel units P closest to the first boundary 1aa, at least one front electrode 4 is located between two adjacent pixel units P. That is to say, the front electrodes 4 and the pixel units P intersect with at least one straight line (e.g., the straight line CC) parallel to the first boundary 1aa at the same time, which is conducive to increasing an area ratio of the display region AA on the first surface 1a of the substrate 1. That is to say, the front electrodes 4 may not occupy an area of the peripheral region AN, which may reduce an area ratio of the peripheral region AN of the display panel 10 on the first surface 1a of the substrate 1, thereby narrowing the frame to a large extent and improving the display effect of the display panel 10.

Alternatively, as shown in FIG. 5B, FIG. 5B is a diagram showing a structure of a partial region of the display panel 10, in accordance with some embodiments of the present disclosure. The plurality of front electrodes 4 are arranged at intervals in the first direction X. The plurality of front electrodes 4 are located within the peripheral region AN of the display panel 10, and the front electrodes 4 are closer to the first boundary 1aa than the pixel units P. There is no straight line parallel to the first boundary 1aa that intersects the front electrodes 4 and the pixel units P at the same time. In this way, although the area ratio of the peripheral region AN of the display panel 10 on the first surface 1a of the substrate 1 will increase, the front electrodes 4 may be disposed in a large space. Correspondingly, in a case where the shape and size of the front electrodes 4 are unchanged, a lot of front electrodes 4 may be provided, thereby reducing the design difficulty.

Some embodiments of the present disclosure are exemplarily described below by considering an example in which the plurality of front electrodes 4 are located within the display region AA of the display panel 10. However, the embodiments of the present disclosure include but are not limited to this. For example, the plurality of front electrodes 4 may also be located within the peripheral region AN of the display panel 10.

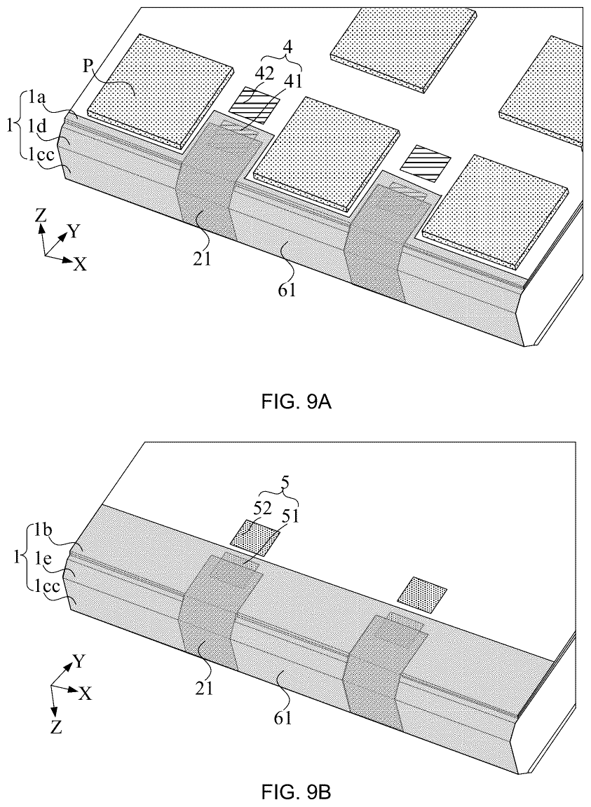

For example, as shown in FIG. 6, FIG. 6 is a diagram showing a structure of a partial region of the display panel 10, in accordance with some embodiments. The plurality of back electrodes 5 are arranged at intervals in the first direction X.

In some embodiments, with continued reference to FIGS. 3, 5A and 6, an end of each of the plurality of connection leads 2 is connected to one front electrode 4 located on the first surface 1a of the substrate 1, and another end of each of the plurality of connection leads 2 is connected to one back electrode 5 located on the second surface 1b of the substrate 1. As a result, a bonding region of the display panel 10 may be transferred to the second surface 1b of the display panel 10, so that an area of the peripheral region AN of the display panel 10 may be reduced, which is conducive to improving the screen-to-body ratio of the display panel 10.

Furthermore, the screen-to-body ratio of the display apparatus 100 including the display panel 10 may also be improving, which is conducive to achieving a narrow frame of the display apparatus 100 and improving the display effect of the display apparatus 100.

Furthermore, in a case where the tiled display apparatus 1000 includes a plurality of display panels 10, in an example where the peripheral region AN of the display panel 10 is located on a side of the display region AA of the display panel 10, as shown in FIG. 1, the plurality of display panels 10 are arranged in a plurality of rows in the first direction X and arranged in a plurality of rows in the second direction Y. The peripheral regions AN of the display panels 10 are all arranged along the first direction X in the plurality of display panels 10 tiled together. In this way, there is basically no tiling gap in the first direction X between two adjacent display panels 10 in the plurality of display panels 10 arranged in a row in the first direction X, and there is a tiling gap between two adjacent display panels 10 in the plurality of display panels 10 arranged in a row in the second direction Y. That is to say, a dimension of the tiling gap between two adjacent display panels 10 in the plurality of display panels 10 arranged in a row in the first direction X is less than a dimension of the tiling gap between two adjacent display panels 10 in the plurality of display panels 10 arranged in a row in the second direction Y.

When the tiled display apparatus 1000 is viewed, since areas of the peripheral regions AN of the display panels 10 are lesser, the dimension of the tiling gap between two adjacent display panels 10 in the plurality of display panels 10 arranged in a row in the second direction Y is also lesser, and the tiling gap between two adjacent display panels 10 is difficult to be found by the eyes within the viewing distance, so that the display images of the tiled display apparatus 1000 are relatively complete and may present a good display effect.

With the continuous development of the display panels 10, users have higher and higher requirements on the refresh rate, brightness and pixels per inch (PPI) of the display panels 10. In order to improve the refresh rate, brightness and pixels per inch (PPI) of the display panels 10, a lot of signals are required to be transmitted from the circuit board to the display region AA of the display panel 10, and a lot of signal transmission may be achieved by increasing the number of connection leads 2.

With continued reference to FIG. 4, in a case where the number of connection leads 2 increases, the arrangement of a lot of connection leads 2 on the substrate 1 (specifically, the first surface 1a, the first chamfered surface 1d, the selected side surface 1cc, the second chamfered surface 1e and the second surface 1b of the substrate 1) may be achieved by reducing a line width K1 of each connection lead 2 and/or a distance d1 between two adjacent connection leads 2, which means that the density of the connection leads 2 is increased.

It will be noted that, the “line width of the connection lead 2” refers to a dimension of the connection lead 2 in the first direction X. The following statement about “the line width of the connection lead 2” also follows this description.

The “distance between two adjacent connection leads 2” refers to a distance between two adjacent connection leads 2 in the first direction X. The following statement about “the distance between two adjacent connection leads 2” also follows this description.

In a case where the line width K1 of the connection lead 2 is reduced, for example, in a case where the connection leads 2 is formed by a printing process, the accuracy of the printing needle T is required to be high, which increases the difficulty of fabricating the connection leads 2. Moreover, since the line width K1 of the connection lead 2 is lesser, there may be a risk of open circuit in some regions of the connection lead 2, which reduces the reliability of the connection leads 2 and easily affects the normal display of the display panel 10.

In a case where the distance d1 between two adjacent connection leads 2 is reduced, the short circuit is likely to occur between the two adjacent connection leads 2, which also affects the normal display of the display panel 10.

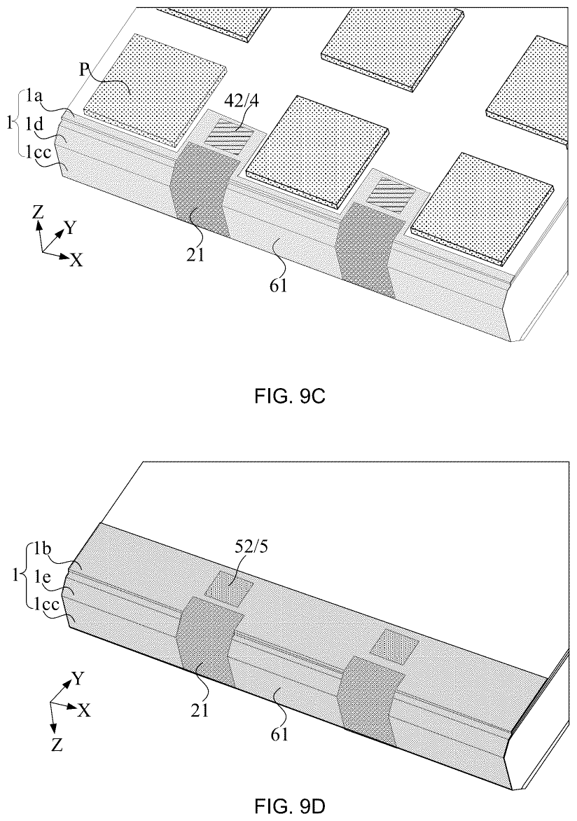

On this basis, in some embodiments, as shown in FIG. 7, FIG. 7 is a diagram showing a structure of the display panel 10, in accordance with some embodiments. The plurality of connection leads 2 include a first connection lead 21 and a second connection lead 22. The first connection lead 21 and the second connection lead 22 are adjacent to each other and disposed in different layers in a direction perpendicular to the surface of the substrate 1.

By making the adjacent first connection lead 21 and second connection lead 22 of the plurality of connection leads 2 disposed in different layers, that is, by making the plurality of connection leads 2 located in different film layers, the arrangement of the plurality of connection leads 2 is changed from a planar arrangement to a three-dimensional arrangement. In one aspect, the restriction of the planar space on the arrangement of the plurality of connection leads 2 may be reduced, and the line widths K1 of the connection leads 2 may be widened, which is conducive to reducing the difficulty of fabricating the connection leads 2, and improving the reliability of the connection leads 2, thereby ensuring the normal display of the display panel 10.

In another aspect, the distance d1 between two adjacent first connection leads 21 and the distance d1 between two adjacent second connection leads 22 may also be increased, so that the probability of short circuit between two adjacent first connection leads 21 and the probability of the short circuit between two adjacent second connection leads 22 may be reduced, thereby ensuring the normal display of the display panel 10.

It will be noted that, for the convenience of the description of the first connection lead 21 and the second connection lead 22, the second connection lead 22 is made transparent in FIG. 7, so as to expose the first connection lead 21 relatively closer to the substrate 1.

For example, the first connection lead 21 and the second connection lead 22 are disposed in different layers, that is, the first connection lead 21 and the second connection lead 22 are located in different film layers. Therefore, when the first connection lead 21 and the second connection lead 22 are formed, one of the first connection lead 21 and the second connection lead 22 may be formed first, and then another of the first connection lead 21 and the second connection lead 22 is formed.

For example, with continued reference to FIG. 7, based on a case where the first connection lead 21 is closer to the substrate 1 than the second connection lead 22, the first connection lead 21 may be formed first, and then the second connection lead 22 may be formed on a side of the first connection lead 21 away from the substrate 1.

For example, in addition to the film layer for providing the first connection lead 21 and the film layer for providing the second connection lead 22, other film layers for providing the connection leads 2 may also be formed. The film layer for providing the first connection lead 21, the film layer for providing the second connection lead 22, and other film layers for providing the connection leads 2 may be stacked in the direction perpendicular to the surface of the substrate 1. The restriction of the plane space on the arrangement of the plurality of connection leads 2 may be further reduced, which is conducive to further reducing the difficulty of fabricating the connection leads 2 and improving the reliability of the connection leads 2, thereby ensuring the normal display of the display panel 10.

For example, the first connection lead 21 and the second connection lead 22 transmit different signals. For example, the signals transmitted by the first connection lead 21 and the second connection lead 22 may include a Vdd signal, a Vss signal, a Data signal, a Vinit signal, and a Reset signal.

For example, one of the first connection lead 21 and the second connection lead 22 is in contact with the surface of the substrate 1.

For example, with continued reference to FIG. 7, the first connection lead 21 may be in contact with the surface of the substrate 1 based on a case where the first connection lead 21 is closer to the substrate 1 than the second connection lead 22. For example, with continued reference to FIG. 7, since the first connection lead 21 and the second connection lead 22 are adjacent to each other in the direction perpendicular to the surface of the substrate 1 (e.g., the first connection lead 21 and the second connection lead 22 are adjacent to each other in the second direction Y on the selected side surface 1cc of the substrate 1), orthogonal projections of the first connection lead 21 and the second connection lead 22 on the substrate 1 may at least partially overlap with each other.

With continued reference to FIG. 7, considering orthogonal projections of the first connection lead 21 and the second connection lead 22 on a plane where the selected side surface 1cc of the substrate 1 is located as an example, for example, in the region FF, the orthogonal projections of the first connection lead 21 and the second connection lead 22 on the plane where the selected side surface 1cc of the substrate 1 is located partially overlap with each other.

For another example, in the region DD, an area of the orthogonal projection of the first connection lead 21 on the plane where the selected side surface 1cc of the substrate 1 is located is less than an area of the orthogonal projection of the second connection lead 22 on the plane where the selected side surface 1cc of the substrate 1 is located, and the orthogonal projection of the first connection lead 21 on the plane where the selected side surface 1cc of the substrate 1 is located is within the orthogonal projection of the second connection lead 22 on the plane where the selected side surface 1cc of the substrate 1 is located.

For yet another example, in the region EE, an area and shape of the orthogonal projection of the first connection lead 21 on the plane where the selected side surface 1cc of the substrate 1 is located are the same as an area and shape of the orthogonal projection of the second connection lead 22 on the plane where the selected side surface 1cc of the substrate 1 is located, and the orthogonal projection of the first connection lead 21 on the plane where the selected side surface 1cc of the substrate 1 is located coincides with the orthogonal projection of the second connection lead 22 on the plane where the selected side surface 1cc of the substrate 1 is located.

For example, with continued reference to FIG. 7, the line width of the first connection lead 21 is K1, and the line width of the second connection lead 22 is K1′. The line width K1 of the first connection lead 21 and the line width K1′ of the second connection lead 22 may be same. For example, the line width K1 is equal to the line width K1′ in the region EE.

Alternatively, the line width K1 of the first connection lead 21 and the line width K1′ of the second connection lead 22 may also be different. In a case where the reliability of the first connection lead 21 and the second connection lead 22 is ensured, the line width K1 of the first connection lead 21 and the line width K1′ of the second connection lead 22 may be set based on actual requirements.

For example, the line width K1 of the first connection lead 21 may be set according to an area of an orthogonal projection of the front electrode 4 connected to the first connection lead 21 on the first surface 1a of the substrate 1, or an area of an orthogonal projection of the back electrode 5 connected to the first connection lead 21 on the second surface 1b of the substrate 1, so that the area of the orthogonal projection of the front electrode 4 connected to the first connection lead 21 on the first surface 1a of the substrate 1, or the area of the orthogonal projection of the back electrode 5 connected to the first connection lead 21 on the second surface 1b of the substrate 1, is positively correlated with the line width K1 of the first connection lead 21. That is to say, the greater the area of the orthogonal projection of the front electrode 4 connected to the first connection lead 21 on the first surface 1a of the substrate 1, or the greater the area of the orthogonal projection of the back electrode 5 connected to the first connection lead 21 on the second surface 1b of the substrate 1, the greater the line width K1 of the first connection lead 21.

Similarly, the line width K1′ of the second connection lead 22 may be set according to an area of an orthogonal projection of the front electrode 4 connected to the second connection lead 22 on the first surface 1a of the substrate 1, or an area of an orthogonal projection of the back electrode 5 connected to the second connection lead 22 on the second surface 1b of the substrate 1, so that the area of the orthogonal projection of the front electrode 4 connected to the second connection lead 22 on the first surface 1a of the substrate 1, or the area of the orthogonal projection of the back electrode 5 connected to the second connection lead 22 on the second surface 1b of the substrate 1, is positively correlated with the line width K1′ of the second connection lead 22. That is to say, the greater the area of the orthogonal projection of the front electrode 4 connected to the second connection lead 22 on the first surface 1a of the substrate 1, or the greater the area of the orthogonal projection of the back electrode 5 connected to the second connection lead 22 on the second surface 1b of the substrate 1, the greater the line width K1′ of the second connection lead 22.

For example, the line width K1 of the first connection lead 21 may be greater than the line width K1′ of the second connection lead 22, or, as shown in FIG. 7, the line width K1 of the first connection lead 21 may also be less than the line width K1′ of the second connection lead 22 in the region DD.

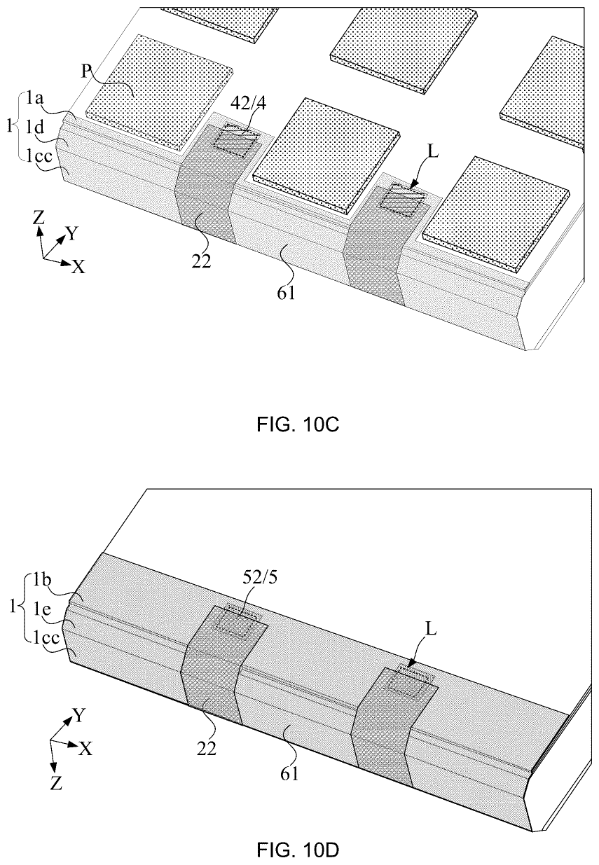

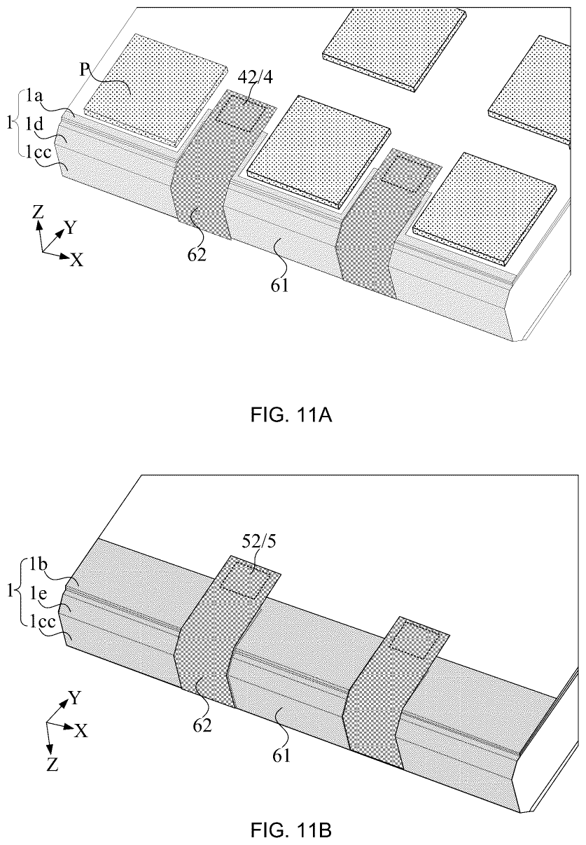

For example, as shown in FIGS. 9A, 9C, 10A and 10C, FIGS. 9A, 9C, 10A and 10C are all a diagram showing a structure of a partial region of the display panel 10, in accordance with some embodiments of the present disclosure. Based on a case where the plurality of front electrodes 4 are located within the display region AA of the display panel 10 in the embodiment shown in FIG. 5A, the connection leads 2 (i.e., the first connection lead 21 and the second connection lead 22) connected to the plurality of front electrodes 4 may also be disposed between two pixel units P adjacent to each other in the first direction X.

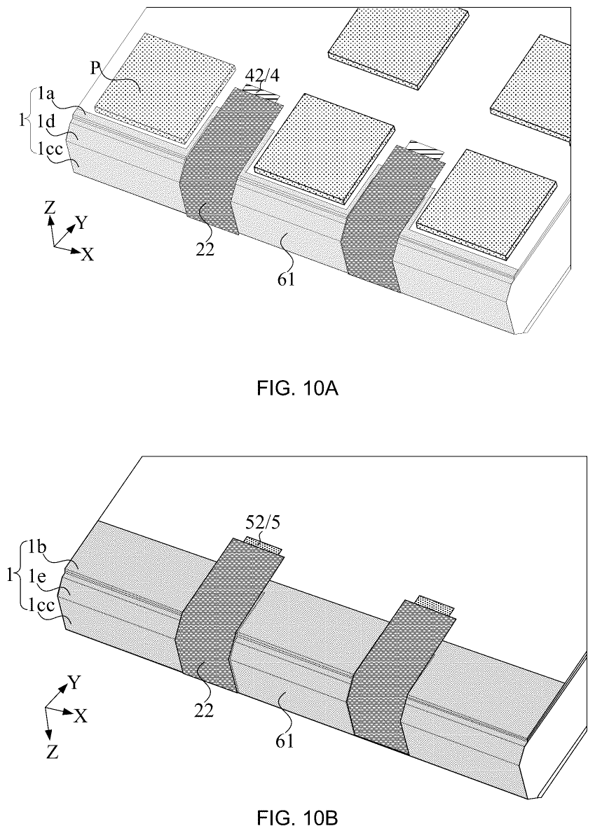

In some embodiments, as shown in FIGS. 8A, 8B, 9A, 9B, 9C, and 9D, FIGS. 8A, 8B, 9B, and 9D are all a diagram showing a structure of a partial region of the display panel 10, in accordance with some embodiments of the present disclosure. The display panel 10 further includes a first insulating layer 61. The first insulating layer 61 is located between the first connection lead 21 and the second connection lead 22. The first insulating layer 61 may insulate the first connection lead 21 and the second connection lead 22 from each other, thereby preventing the short circuit between the first connection lead 21 and the second connection lead 22 and ensuring the normal display of the display panel 10.

For example, the material for forming the first insulating layer 61 may include a thermosetting resin or a UV resin. The first insulating layer 61 may be formed by a printing process.

The material for forming the first insulating layer 61 may also include silicon nitride, silicon oxide or silicon oxynitride. The first insulating layer 61 may also be formed by a chemical vapor deposition process.

For example, the first insulating layer 61 covers at least the first connection lead 21, and the front electrode 4 and back electrode 5 connected to the first connection lead 21.

For example, as shown in FIGS. 8A and 8B, the first insulating layer 61 may cover only the first connection lead 21, and the front electrode 4 and back electrode 5 connected to the first connection lead 21. On the basis of playing an insulating role, the material used to form the first insulating layer 61 may also be saved, which is conducive to reducing the manufacturing cost of the display panel 10.

It will be noted that the first insulating layer 61 includes a plurality of separated insulating blocks 61a, each insulating block 61a correspondingly covers one first connection lead 21 and the front electrode 4 and back electrode 5 connected to the first connection lead 21. FIGS. 8A and 8B illustrate a situation where orthogonal projections of the insulating block 61a and the first connection lead 21 completely overlaps with each other, and therefore the first connection lead 21 is not shown.

For another example, as shown in FIGS. 9A and 9B, the first insulating layer 61 may also cover the selected side surface 1cc of the substrate 1. In a case where the first insulating layer 61 covering the selected side surface 1cc is formed on the selected side surface 1cc of the substrate 1, the first insulating layer 61 located on the selected side surface 1cc may simultaneously cover the portion of the first connection lead 21 located on the selected side surface 1cc, and it is not necessary to separately form the first insulating layer 61 covering the portion of the first connection lead 21 located on the selected side surface 1cc correspondingly within a region where the first connection lead 21 is disposed. This is conducive to reducing the difficulty of fabricating the first insulating layer 61 and improving the fabrication efficiency of the first insulating layer 61.

For another example, as shown in FIGS. 9A and 9B, in a case where the substrate 1 includes the first chamfered surface 1d and the second chamfered surface 1e, the first insulating layer 61 may also cover the first chamfered surface 1d and the second chamfered surface 1e. In a case where the first insulating layer 61 covering the first chamfered surface 1d and the second chamfered surface 1e is formed on the first chamfered surface 1d and the second chamfered surface 1e of the substrate 1, the first insulating layer 61 located on the first chamfered surface 1d and the second chamfered surface 1e may simultaneously cover the portions of the first connection lead 21 located on the first chamfered surface 1d and the second chamfered surface 1e, and it is not necessary to separately form the first insulating layer 61 covering the portions of the first connection lead 21 located on the first chamfered surface 1d and the second chamfered surface 1e correspondingly within the region where the first connection lead 21 is disposed. This is conducive to reducing the difficulty of fabricating the first insulating layer 61 and improving the fabrication efficiency of the first insulating layer 61.

For another example, as shown in FIG. 9B, the first insulating layer 61 may also cover a region between two adjacent back electrodes 5 in the first direction X on the second surface 1b of the substrate 1. In a case where the first insulating layer 61 covering the back electrode 5 and the region between two back electrodes 5 adjacent in the first direction X is formed on the second surface 1b of the substrate 1, the first insulating layer 61 covering the back electrodes 5 and the first insulating layer 61 covering the region between two back electrodes 5 adjacent in the first direction X may be formed simultaneously, and it is not necessary to separately form the first insulating layer 61 covering the portion of the first connection lead 21 located on the second surface 1b correspondingly within the region where the first connection lead 21 is disposed. This is conducive to further reducing the difficulty of fabricating the first insulating layer 61 and further improving the fabrication efficiency of the first insulating layer 61.

For yet another example, as shown in FIG. 9C, on the first surface 1a of the substrate 1, the first insulating layer 61 may also cover the front electrode 4 that is not connected to the first connection lead 21, which is conducive to increasing an area covered by the first insulating layer 61 and avoiding a case that the first insulating layer 61 is insufficient to cover the front electrode 4 connected to the first connection lead 21, and improving the insulation performance of the first insulating layer 61.

As shown in FIG. 9D, on the second surface 1b of the substrate 1, the first insulating layer 61 may also cover the back electrode 5 that is not connected to the first connection lead 21, which is conducive to increasing the area covered by the first insulating layer 61 and avoiding a case that the first insulating layer 61 is insufficient to cover the back electrode 5 connected to the first connection lead 21, and further improving the insulation performance of the first insulating layer 61.

It will be noted that, for the convenience of the description of the first connection lead 21 and the first insulating layer 61, the first insulating layer 61 is made transparent in FIGS. 9A and 9B, so as to expose the first connection lead 21.

Some embodiments of the present disclosure are exemplarily described below by considering an example in which the first insulating layer 61 covers the selected side surface 1cc, the first chamfered surface 1d, the second chamfered surface 1e, the first connection lead 21, and the front electrode 4 and back electrode 5 connected to the first connection lead 21.

It may be understood that, as shown in FIGS. 10A, 10B, 10C and 10D, FIGS. 10A, 10B, 10C and 10D are all a diagram showing a structure of a partial region of the display panel 10, in accordance with some embodiments of the present disclosure. The second connection lead 22 is located on a side of the first insulating layer 61 away from the first connection lead 21. That is to say, the first connection lead 21 and the second connection lead 22 are located on two opposite sides of the first insulating layer 61, respectively.

For example, with continued reference to FIGS. 10A and 10B, in a case where the first insulating layer 61 does not cover the front electrode 4 and back electrode 5 that are not connected to the first connection lead 21, the first connection lead 21 is directly connected to the front electrode 4 and the back electrode 5.

The second connection lead 22 is also directly connected to the front electrode 4 and the back electrode 5.

Alternatively, with continued reference to FIGS. 10C and 10D, in a case where the first insulating layer 61 covers the front electrode 4 and back electrode 5 that are not connected to the first connection lead 21, the first connection lead 21 is directly connected to the front electrode 4 and the back electrode 5.

The second connection lead 22 is connected the front electrode 4 and the back electrode 5 through via holes L. The via hole L, for example, penetrates through the first insulating layer 61.

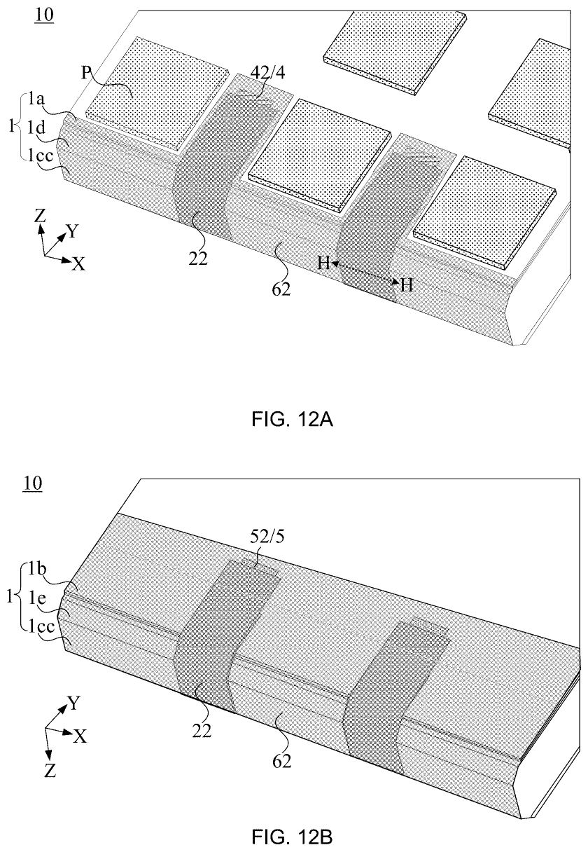

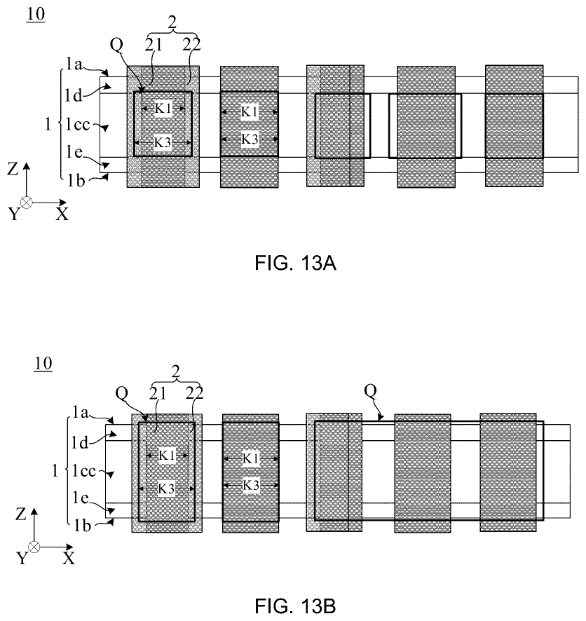

In some embodiments, as shown in FIGS. 11A, 11B, 12A and 12B, FIGS. 11A, 11B, 12A and 12B are all a diagram showing a structure of a partial region of the display panel 10, in accordance with some embodiments of the present disclosure. The display panel 10 further includes a protective layer 62. The protective layer 62 covers at least the second connection lead 22, and the front electrode 4 and back electrode 5 connected to the second connection lead 22.

The protective layer 62 may not only play an insulating role to prevent the short circuit between the second connection lead 22, the front electrode 4 and back electrode 5 connected to the second connection lead 22 and other circuits in the display panel 10, but also protect the second connection lead 22, the front electrode 4 and back electrode 5 connected to the second connection lead 22, and prevent the second connection lead 22, and the front electrode 4 and back electrode 5 connected to the second connection lead 22 from being corroded or oxidized due to their exposed surfaces.

For example, as shown in FIGS. 11A and 11B, the protective layer 62 may cover only the second connection lead 22, and the front electrode 4 and back electrode 5 connected to the second connection lead 22. On the basis of playing an insulating role, the material used to form the protective layer 62 may also be saved, which is conducive to reducing the manufacturing cost of the display panel 10.

For another example, as shown in FIGS. 12A and 12B, the protective layer 62 may also cover the selected side surface 1cc of the substrate 1. In a case where the protective layer 62 covering the selected side surface 1cc is formed on the selected side surface 1cc of the substrate 1, the protective layer 62 located on the selected side surface 1cc may simultaneously cover the portion of the second connection lead 22 located on the selected side surface 1cc, and it is not necessary to separately form the protective layer 62 covering the portion of the second connection lead 22 located on the selected side surface 1cc correspondingly within a region where the second connection lead 22 is disposed. This is conducive to reducing the difficulty of fabricating the protective layer 62 and improving the fabrication efficiency of the protective layer 62.

For another example, as shown in FIGS. 12A and 12B, in a case where the substrate 1 includes the first chamfered surface 1d and the second chamfered surface 1e, the protective layer 62 may also cover the first chamfered surface 1d and the second chamfered surface 1e. In a case where the protective layer 62 covering the first chamfered surface 1d and the second chamfered surface 1e is formed on the first chamfered surface 1d and the second chamfered surface 1e of the substrate 1, the protective layer 62 located on the first chamfered surface 1d and the second chamfered surface 1e may simultaneously cover the portions of the second connection lead 22 located on the first chamfered surface 1d and the second chamfered surface 1e, and it is not necessary to separately form the protective layer 62 covering the portions of the second connection lead 22 located on the first chamfered surface 1d and the second chamfered surface 1e correspondingly within the region where the second connection lead 22 is disposed. This is conducive to reducing the difficulty of fabricating the protective layer 62 and improving the fabrication efficiency of the protective layer 62.

For another example, as shown in FIG. 12B, the protective layer 62 may also cover a region between two adjacent back electrodes 5 in the first direction X on the second surface 1b of the substrate 1. In a case where the protective layer 62 covering the back electrode 5 and the region between two back electrodes 5 adjacent in the first direction X is formed on the second surface 1b of the substrate 1, the protective layer 62 covering the back electrode 5 and the protective layer 62 covering the region between two back electrodes 5 adjacent in the first direction X may be formed simultaneously, and it is not necessary to separately form the protective layer 62 covering the portion of the second connection lead 22 located on the second surface 1b correspondingly within the region where the second connection lead 22 is disposed. This is conducive to further reducing the difficulty of fabricating the protective layer 62 and further improving the fabrication efficiency of the protective layer 62.

It will be noted that, for the convenience of the description of the second connection lead 22 and the protective layer 62, the protective layer 62 is made transparent in FIGS. 12A and 12B, so as to expose the second connection lead 22.

For example, the material for forming the protective layer 62 may include a thermosetting resin or a UV resin. The protective layer 62 may be formed by a printing process.

The material for forming the protective layer 62 may also include silicon nitride, silicon oxide or silicon oxynitride. The protective layer 62 may also be formed by a chemical vapor deposition process.

In the tiled display apparatus 1000, a size of the tiling gap (the gap between two adjacent display panels 10) is an important factor affecting the display effect of the tiled display apparatus 1000. Since the first connection lead 21, the first insulating layer 61, the second connection lead 22 and the protective layer 62 are sequentially arranged in the second direction Y on the selected side surface 1cc of the substrate 1, the first connection lead 21, the first insulating layer 61, the second connection lead 22 and the protective layer 62 occupy the space on the selected side surface 1cc of the substrate 1, which is not conducive to narrowing the frame of the display panel 10, so that the tiling gaps increase when the display panels 10 are tiled, and abnormal display in the tiling gap regions is prone to occur in the tiled display apparatus 1000, such as bright gaps and other defects, thereby affecting the display effect of the tiled display apparatus 1000.

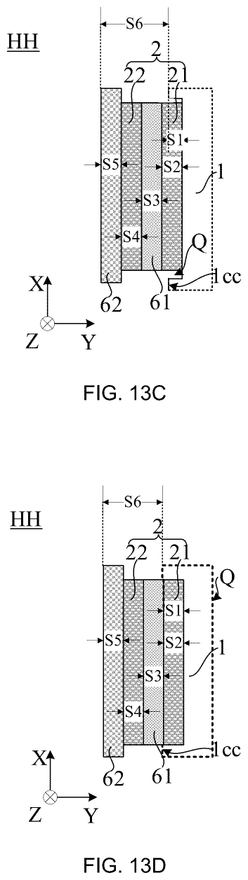

On this basis, as shown in FIGS. 13A and 13B, FIGS. 13A and 13B are both a diagram showing a structure of a partial region of the display panel 10, in accordance with some embodiments of the present disclosure. The display panel 10 further includes at least one depressed region Q, and the at least one depressed region Q is located on at least the selected side surface 1cc of the substrate 1.

It will be noted that the depressed region Q means that a groove is disposed on at least the selected side surface 1cc of the substrate 1, so as to form the depressed region Q. That is to say, the depressed region Q is recessed toward the inside of the substrate 1.

For example, with continued reference to FIG. 13A, the depressed region Q may be located only on the selected side surface 1cc of the substrate 1.

Alternatively, with continued reference to FIG. 13B, based on a case that the depressed region Q is located on the selected side surface 1cc of the substrate 1, the depressed region Q may also extend to the first chamfered surface 1d and the second chamfered surface 1e of the substrate 1.

Alternatively, the depressed region Q may also extend to the first surface 1a and the second surface 1b of the substrate 1.

With continued reference to FIGS. 13A and 13B, an orthogonal projection of the one of the first connection lead 21 and the second connection lead 22 that is closer to the substrate 1 on the selected side surface 1cc of the substrate 1 is located within the depressed region Q.

For example, as shown in FIGS. 13A and 13B, the first connection lead 21 is closer to the substrate 1 than the second connection lead 22, and the orthogonal projection of the first connection lead 21 on the selected side surface 1cc of the substrate 1 is located within the depressed region Q.

Some embodiments of the present disclosure are exemplarily described below by considering an example in which the first connection lead 21 is closer to the substrate 1 than the second connection lead 22.

For example, with continued reference to FIG. 13A, the display panel 10 may include a plurality of depressed regions Q, and the orthogonal projection of one first connection lead 21 on the selected side surface 1cc of the substrate 1 is located within one depressed region Q.

Alternatively, with continued reference to FIG. 13B, the orthogonal projections of a plurality of (e.g., three) first connection leads 21 on the selected side surface 1cc of the substrate 1 are located within one depressed region Q.

In some embodiments, with continued reference to FIGS. 13A and 13B, in a case where the orthogonal projection of one first connection lead 21 on the selected side surface 1cc of the substrate 1 is located within one depressed region Q, a ratio of a dimension K3 of the depressed region Q in the first direction X to a dimension K1 (i.e., the line width of the first connection lead 21) of the first connection lead 21 in the first direction X is within a range of 1 to 2, inclusive.

For example, the ratio of the dimension K3 of the depressed region Q in the first direction X to the dimension K1 (i.e., the line width of the first connection lead 21) of the first connection lead 21 in the first direction X may be 1, 1.2, 1.3, 1.5, 1.6, 1.8 or 2.

It may be understood that in a case where the ratio of the dimension K3 of the depressed region Q in the first direction X to the dimension K1 (i.e., the line width of the first connection lead 21) of the first connection lead 21 in the first direction X is greater than 1, the dimension K3 of the depressed region Q in the first direction X is greater than the dimension K1 (i.e., the line width of the first connection lead 21) of the first connection lead 21 in the first direction X, which is helpful for the first connection lead 21 to be formed within the depressed region Q, thereby reducing the probability that the orthogonal projection of the first connection lead 21 on the selected side surface 1cc of the substrate 1 is partially located outside the depressed region Q due to the misalignment of the first connection lead 21 and the depressed region Q.

In a case where the ratio of the dimension K3 of the depressed region Q in the first direction X to the dimension K1 (i.e., the line width of the first connection lead 21) of the first connection lead 21 in the first direction X is 1, the dimension K3 of the depressed region Q in the first direction X is the same as the dimension K1 (i.e., the line width of the first connection lead 21) of the first connection lead 21 in the first direction X. The dimension K3 of the depressed region Q in the first direction X is lesser, which may reduce the cost of forming the depressed region Q and further reduce the production cost of the display panel 10.

As shown in FIGS. 13C, 13D and 13E, FIGS. 13C, 13D and 13E are all a sectional view of the display panel 10 in FIG. 12A taken along the section line H-H. It will be noted that FIGS. 13C, 13D and 13E each are sectional views of the display panel 10 in FIG. 12A taken along the section line H-H in a case where the depressed region Q of the display panel 10 has different depths (i.e., dimensions of the depressed regions Q in the second direction Y).

The depth (i.e., the dimension of the depressed region Q in the second direction Y) of the depressed region Q is S1. Since the orthogonal projection of the first connection lead 21 on the selected side surface 1cc of the substrate 1 is located within the depressed region Q, at least a portion of the first connection lead 21 is located within the depressed region Q.

In a case where at least a portion of the first connection lead 21 is located within the depressed region Q, the space occupied by the first connection lead 21, the first insulating layer 61, the second connection lead 22 and the protective layer 62 on the selected side surface 1cc of the substrate 1 may be reduced. That is to say, a distance S6 between a side of the protective layer 62 away from the selected side surface 1cc and the selected side surface 1cc is reduced, which is conducive to narrowing the frame of the display panel 10, thereby reducing the distances of the tiling gaps when the display panels 10 are tiled. As a result, when the tiled display apparatus 1000 is actually viewed, the tiling gap between two adjacent display panels 10 is difficult to be found by the eyes within the viewing distance, thereby avoiding abnormal display in the tiling gap regions in the tiled display apparatus 1000, ensuring the normal display of the tiled display apparatus 1000, and presenting a good display effect.

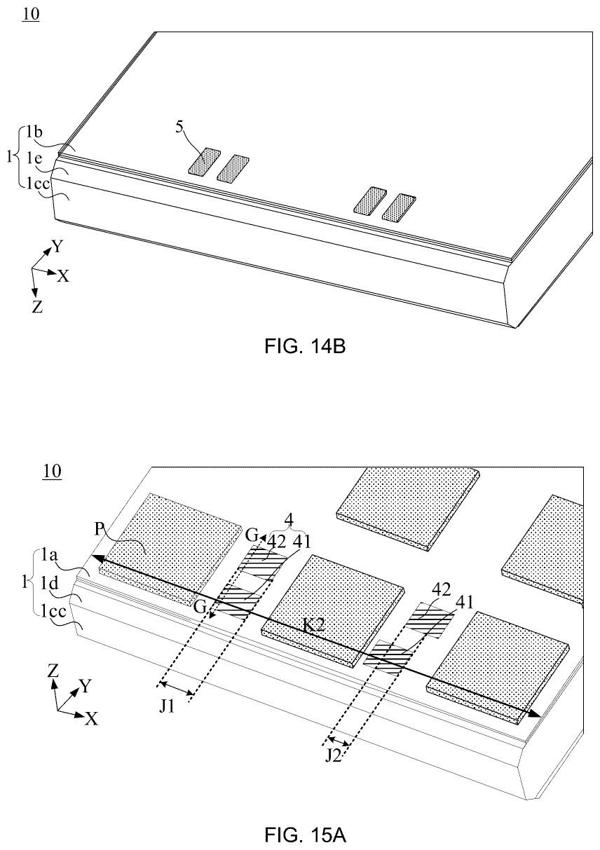

As shown in FIGS. 13C, 13D and 13E, and in combination with FIG. 15B, FIG. 15B is a diagram showing a structure of a partial region of the display panel 10, in accordance with some embodiments of the present disclosure. A minimum distance between an edge of a front electrode 4 in the plurality of front electrodes 4 that is closest to the selected side surface 1cc of the substrate 1 and the first boundary 1aa of the first surface 1a is d2. It may be understood that the depth (i.e., the dimension of the depressed region Q in the second direction Y) of the depressed region Q is S1 and should be less than or equal to d2, so as to avoid exposing surfaces of some front electrodes 4 proximate to the substrate 1.

For example, the minimum distance d2 between the edge of the front electrode 4 in the plurality of front electrodes 4 that is closest to the selected side surface 1cc of the substrate 1 and the first boundary 1aa of the first surface 1a may be within a range of 50 μm to 100 μm, inclusive.

For example, the minimum distance d2 between the edge of the front electrode 4 in the plurality of front electrodes 4 that is closest to the selected side surface 1cc of the substrate 1 and the first boundary 1aa of the first surface 1a may be 50 μm, 55 μm, 60 μm, 66 μm, 70 μm, 75 μm, 80 μm, 85 μm, 88 μm, 90 μm, 95 μm or 100 μm.

With continued reference to FIGS. 13C, 13D and 13E, a thickness (i.e., a dimension of the first connection lead 21 in the second direction Y) of the first connection lead 21 is S2, a thickness (i.e., a dimension of the first insulating layer 61 in the second direction Y) of the first insulating layer 61 is S3, a thickness (i.e., a dimension of the second connection lead 22 in the second direction Y) of the second connection lead 22 is S4, and a thickness (i.e., a dimension of the protective layer 62 in the second direction Y) of the protective layer 62 is S5.

For example, as shown in FIG. 13C, the depth S1 (i.e., the dimension of the depressed region Q in the second direction Y) of the depressed region Q may be less than the thickness S2 (i.e., the dimension of the first connection lead 21 in the second direction Y) of the first connection lead 21, and a portion of the first connection lead 21 is located within the depressed region Q.

Alternatively, as shown in FIG. 13D, the depth S1 (i.e., the dimension of the depressed region Q in the second direction Y) of the depressed region Q may be equal to the thickness S2 (i.e., the dimension of the first connection lead 21 in the second direction Y) of the first connection lead 21, and the first connection lead 21 is entirely located within the depressed region Q. The distance S6 between the side of the protective layer 62 away from the selected side surface 1cc and the selected side surface 1cc may be further reduced, which is conducive to narrowing the frame of the display panel 10, thereby reducing the distances of the tiling gaps when the display panels 10 are tiled, avoiding abnormal display in the tiling gap regions in the tiled display apparatus 1000, and ensuring the normal display of the tiled display apparatus 1000.

Alternatively, as shown in FIG. 13E, the depth S1 (i.e., the dimension of the depressed region Q in the second direction Y) of the depressed region Q may be greater than the thickness S2 (i.e., the dimension of the first connection lead 21 in the second direction Y) of the first connection lead 21. For example, the depth S1 (i.e., the dimension of the depressed region Q in the second direction Y) of the depressed region Q is equal to a sum of the thickness S2 (i.e., the dimension of the first connection lead 21 in the second direction Y) of the first connection lead 21, the thickness S3 (i.e., the dimension of the first insulating layer 61 in the second direction Y) of the first insulating layer 61, and the thickness S4 (i.e., the dimension of the second connection lead 22 in the second direction Y) of the second connection lead 22. The first connection lead 21, the first insulating layer 61 and the second connection lead 22 are all located within the depressed region Q. The distance S6 between the side of the protective layer 62 away from the selected side surface 1cc and the selected side surface 1cc may be further reduced, which is conducive to narrowing the frame of the display panel 10, thereby reducing the distances of the tiling gaps when the display panels 10 are tiled, avoiding abnormal display in the tiling gap region in the tiled display apparatus 1000, and ensuring the normal display of the tiled display apparatus 1000.

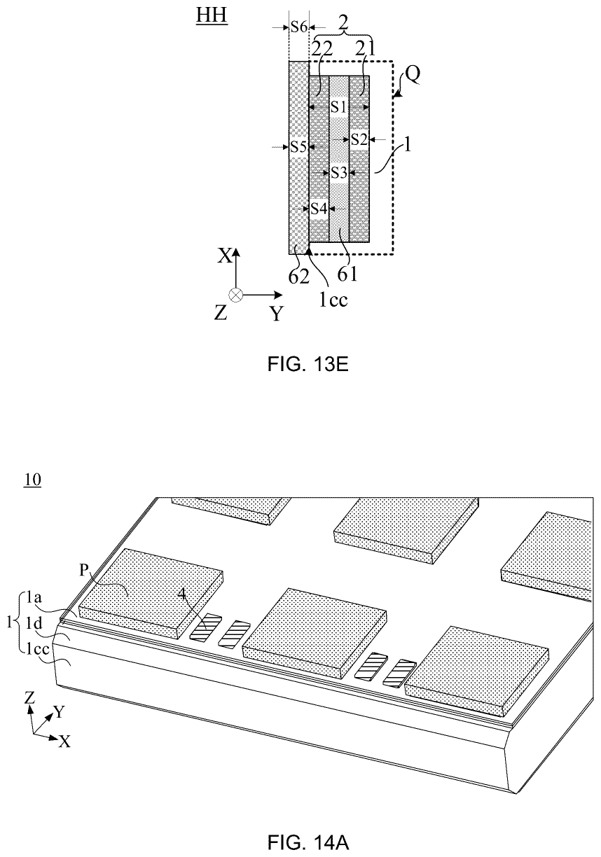

In a case where the number of connection leads 2 increases, the numbers of front electrodes 4 and back electrodes 5 correspondingly connected to the connection leads 2 also increase correspondingly. As shown in FIGS. 14A and 14B, FIGS. 14A and 14B are a diagram showing a structure of a partial region of the display panel 10, in accordance with some embodiments of the present disclosure. By reducing the size of the front electrode 4 and the size of the back electrode 5, it is possible to arrange a large number of front electrodes 4 on the first surface 1a of the substrate 1 and arrange a large number of back electrodes 5 on the second surface 1b of the substrate 1. That is to say, the densities of the front electrodes 4 and the back electrodes 5 increase.

It will be noted that the “size of the front electrode 4″ refers to an area of an orthogonal projection of the front electrode 4 on the first surface 1a of the substrate 1, and the ”size of the back electrode 5″ refers to an area of an orthogonal projection of the back electrode 5 on the second surface 1b of the substrate 1. The following statements about “the size of the front electrode 4″ and ”the size of the back electrode 5″ also follow this description.

In a case where the size of the front electrode 4 is reduced, an overlapping area between the connection lead 2 and the front electrode 4 also be reduced, which may easily cause poor overlapping between the connection lead 2 and the front electrode 4, affect the conductive performance between the connection lead 2 and the front electrode 4, and may cause the display panel 10 to fail to display normally.

On this basis, embodiments of the arrangement of the front electrodes 4 are first described below.

In some embodiments, as shown in FIGS. 15A, 15B and 15C, FIGS. 15A, 15B and 15C are all a diagram showing a structure of a partial region of the display panel 10, in accordance with some embodiments of the present disclosure. The plurality of front electrodes 4 are arranged at intervals in the first direction X and the second direction Y. Compared with the case where the plurality of front electrodes 4 are arranged at intervals only in the first direction X, by arranging the plurality of front electrodes 4 at intervals in the first direction X and the second direction Y, it is possible to reduce the restriction of a dimension K2 of the first surface 1a of the substrate 1 in the first direction X on the arrangement of the plurality of front electrodes 4, so as to ensure the sizes of the front electrodes 4, increase the overlapping area between the connection lead 2 and the front electrode 4, and avoid poor overlapping between the connection lead 2 and the front electrode 4. As a result, it is conducive to improving the conductive performance between the connection lead 2 and the front electrode 4, thereby ensuring the normal display of the display panel 10.

For example, with continued reference to FIGS. 15A, 15B and 15C, the plurality of front electrodes 4 include a first electrode 41 and a second electrode 42, and the first electrode 41 and the second electrode 42 are disposed adjacent to each other. It may be understood that the plurality of front electrodes 4 may also include a plurality of first electrodes 41 and a plurality of second electrodes 42. The first electrodes 41 are arranged at intervals in the first direction X. The second electrodes 42 are also arranged at intervals in the first direction X, and the first electrodes 41 and the second electrodes 42 are arranged alternately in the second direction Y.

It will be noted that, FIGS. 15A, 15B and 15C illustrate an example in which one first electrode 41 and one second electrode 42 are alternately arranged in the second direction Y. However, the arrangement of the first electrodes 41 and the second electrodes 42 in the present disclosure is not limited to this. For example, a plurality of first electrodes 41 and a plurality of second electrodes 42 may also be alternately arranged in the second direction Y.

For example, with continued reference to FIGS. 15A and 15B, the plurality of pixel units P include two pixel units P that are adjacent to each other in the first direction X and both proximate to the selected side surface 1cc of the substrate 1. The first electrode 41 and the second electrode 42 are disposed between the two adjacent pixel units P. It may be understood that in the second direction Y, the first electrodes 41 and the second electrodes 42 do not overlap with the two pixel units P that are adjacent to each other in the first direction X and both proximate to the selected side surface 1cc of the substrate 1.

Alternatively, as shown in FIG. 15C, the plurality of pixel units P include two pixel units P that are adjacent to each other in the first direction X and both proximate to the selected side surface 1cc of the substrate 1. In the second direction Y, the first electrodes 41 and the second electrodes 42 at least partially overlap with the two pixel units P that are adjacent to each other in the first direction X and both proximate to the selected side surface 1cc of the substrate 1, and there is an overlapping region J12.

Some embodiments of the present disclosure are exemplarily described below by considering an example in which the first electrode 41 and the second electrode 42 are disposed between two adjacent pixel units P (i.e., the two pixel units P that are adjacent to each other in the first direction X and both proximate to the selected side surface 1cc of the substrate 1). For example, with continued reference to FIGS. 15A and 15B, the first electrodes 41 are closer to the selected side surface 1cc of the substrate 1 than the second electrodes 42.

For example, as shown in FIG. 15A, the first electrodes 41 and the second electrodes 42 may be of a same size. Alternatively, as shown in FIG. 15B, the sizes of the first electrodes 41 may also be different from the sizes of the second electrodes 42, and the sizes of the first electrodes 41 and the second electrodes 42 may be designed based on actual requirements.

For example, with continued reference to FIGS. 15A and 15B, there is at least a partial overlapping region between the first electrode 41 and the second electrode 42 in the second direction Y.

For example, as shown in FIG. 15A, the first electrode 41 and the second electrode 42 may be arranged in a staggered manner in the second direction Y, and the first electrode 41 and the second electrode 42 partially overlap with each other in the second direction Y and have an overlapping region J2 therebetween.

For another example, as shown in FIG. 15A, the first electrode 41 and the second electrode 42 may be arranged in an array in the second direction Y, and the size of the first electrode 41 is the same as the size of the second electrode 42. The first electrode 41 and the second electrode 42 completely overlap with each other in the second direction Y and have an overlapping region J1 therebetween.

For yet another example, as shown in FIG. 15B, the first electrode 41 and the second electrode 42 may be arranged in an array in the second direction Y, and the size of the first electrode 41 is different from the size of the second electrode 42. One of the first electrode 41 and the second electrode 42 may completely overlap with the other of the first electrode 41 and the second electrode 42 in the second direction Y and there is an overlapping region J3.

In some embodiments, the plurality of front electrodes 4 (first electrodes 41 and second electrodes 42) may be disposed in a conductive layer located on the first surface 1a of the substrate 1.

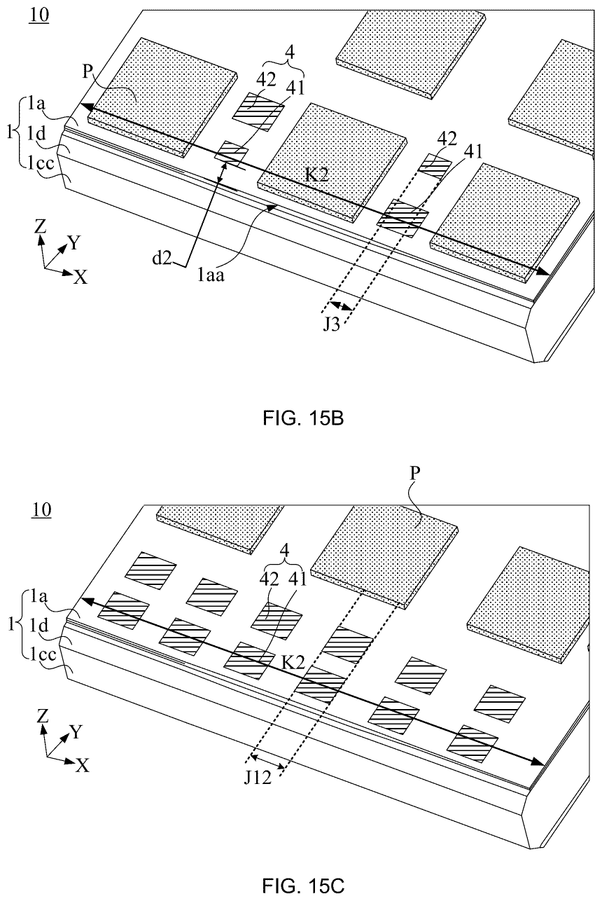

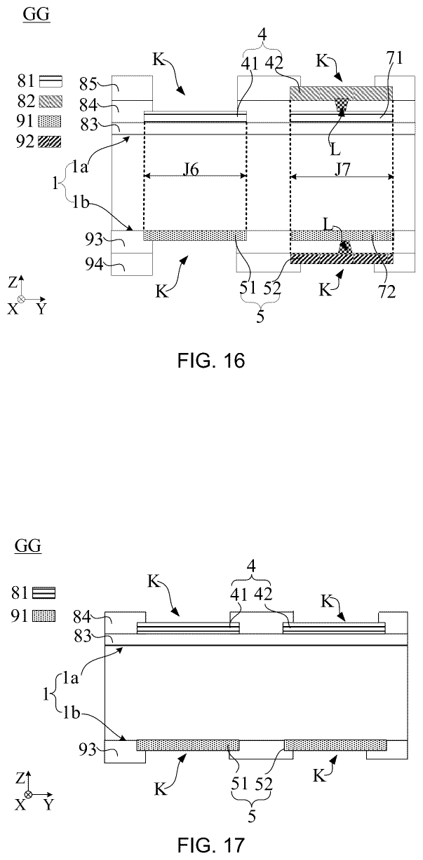

As shown in FIGS. 16 and 17, FIGS. 16 and 17 are both a sectional view of the display panel 10 in FIG. 15A taken along the section line G-G. It will be noted that FIGS. 16 and 17 are sectional views of the display panel 10 in FIG. 15A taken along the section line G-G in a case where the front electrodes 4 and the back electrodes 5 of the display panel 10 have different arrangements.

The first surface 1a of substrate 1 includes a second insulating layer 83, a first conductive layer 81, a third insulating layer 84, a second conductive layer 82 and a fourth insulating layer 85 that are sequentially stacked. The first conductive layer 81 is closer to the first surface 1a of the substrate 1 than the second conductive layer 82.

For example, the first conductive layer 81 may be provided with a gate electrode of the thin film transistor in the driving assembly of the pixel unit P, and the second conductive layer 82 may be provided with a source-drain electrode of the thin film transistor.

For example, the first conductive layer 81 and the second conductive layer 82 may both be obtained by depositing one or more of metal materials such as molybdenum (MO), titanium (Ti), aluminum (Al), copper (Cu), and indium tin oxide (ITO) through a physical vapor deposition (PVD) process.

For example, the first conductive layer 81 or the second conductive layer 82 may be obtained by depositing molybdenum/aluminum/molybdenum (MO/Al/MO), molybdenum/copper/molybdenum (MO/Cu/MO), titanium/copper/titanium (Ti/Cu/Ti) or indium tin oxide/copper (ITO/Cu) through a physical vapor deposition (PVD) process. The oxidation resistance capability of the second conductive layer 82 is greater than that of the first conductive layer 81.

In some embodiments, as shown in FIG. 17, the first electrode 41 may be disposed in the same layer as the second electrode 42.

For example, the first electrode 41 and the second electrode 42 are both located in the first conductive layer 81.

In some other embodiments, with continued reference to FIG. 16, the first electrode 41 and the second electrode 42 may be disposed in different layers, and the first electrode 41 is closer to the first surface 1a of the substrate 1 than the second electrode 42.

By arranging the first electrode 41 and the second electrode 42 in different conductive layers (the first conductive layer 81 and the second conductive layer 82), the plurality of front electrodes 4 are located in different planes, and the arrangement of the plurality of front electrodes 4 (the first electrodes 41 and the second electrodes 42) is changed from a plane arrangement to a three-dimensional arrangement. That is to say, the plurality of front electrodes 4 may not only be arranged at intervals in the first direction X and the second direction Y, but also may be arranged at intervals in the third direction Z, so that the restriction of the plane space on the arrangement of the front electrodes 4 (the first electrodes 41 and the second electrodes 42) may be reduced, the sizes of the front electrodes 4 may be ensured, the overlapping area between the connection lead 2 and the front electrode 4 may be further increased, poor overlapping between the connection lead 2 and the front electrode 4 may be avoided. As a result, it is conducive to improving the conductive performance between the connection lead 2 and the front electrode 4, thereby ensuring the normal display of the display panel 10.

For example, in addition to the conductive layer for providing the first electrodes 41 and the conductive layer for providing the second electrodes 42, other conductive layers for providing the front electrodes 4 may also be formed. The conductive layer for providing the first electrodes 41, the conductive layer for providing the second electrodes 42, and other conductive layers for providing the front electrodes 4 may be stacked in the third direction Z. The restriction of the plane space on the arrangement of the front electrodes 4 may be further reduced, the sizes of the front electrodes 4 may be ensured, and the overlapping area between the connection lead 2 and the front electrode 4 may be further increased, and poor overlapping between the connection lead 2 and the front electrode 4 may be avoided. As a result, it is conducive to further improving the conductive performance of the connection lead 2 and the front electrode 4, thereby ensuring the normal display of the display panel 10.

For example, the first electrodes 41 may be located in the first conductive layer 81, and the second electrodes 42 may be located in the second conductive layer 82.

For example, with continued reference to FIG. 16, an orthogonal projection of the first electrode 41 on the first surface 1a of the substrate 1 does not overlap with an orthogonal projection of the second electrode 42 on the first surface 1a of the substrate 1. That is to say, there is no overlapping region between the orthogonal projection of the first electrode 41 on the first surface 1a of the substrate 1 and the orthogonal projection of the second electrode 42 on the first surface 1a of the substrate 1.

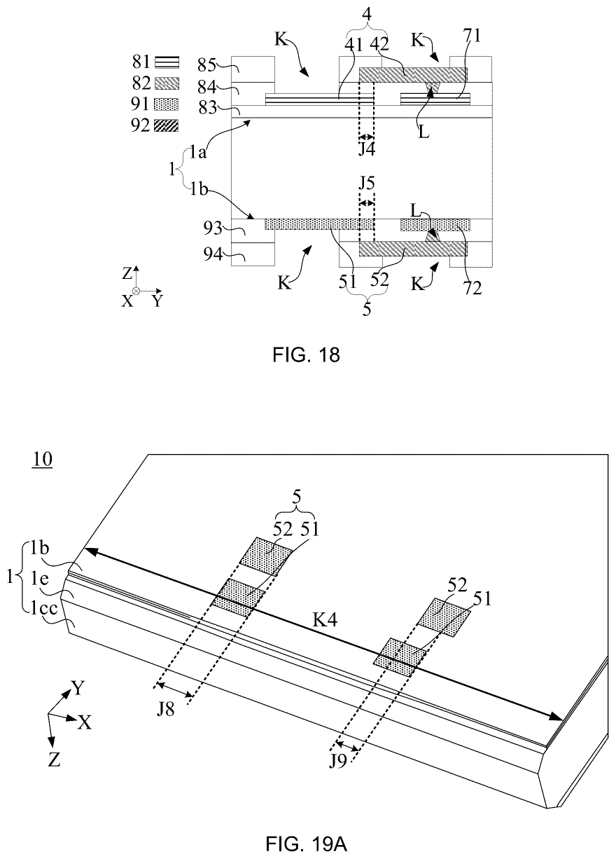

Alternatively, as shown in FIG. 18, FIG. 18 is a sectional view of a partial region of the display panel 10, in accordance with some embodiments of the present disclosure. The orthogonal projection of the first electrode 41 on the first surface 1a of the substrate 1 partially overlaps with the orthogonal projection of the second electrode 42 on the first surface 1a of the substrate 1. That is to say, there is an overlapping region J4 between the orthogonal projection of the first electrode 41 on the first surface 1a of the substrate 1 and the orthogonal projection of the second electrode 42 on the first surface 1a of the substrate 1.

In some embodiments, with continued reference to FIGS. 16, 17 and 18, the display panel 10 further includes a plurality of opening portions K for exposing the plurality of front electrodes 4 (the first electrode 41 and the second electrode 42).

For example, as shown in FIG. 17, the opening portions K may penetrate through the third insulating layer 84 and expose the first electrode 41 and the second electrode 42 located in the first conductive layer 81.

Alternatively, as shown in FIGS. 16 and 18, the opening portion K may penetrate through the fourth insulating layer 85 and expose the second electrode 42 located in the second conductive layer 82. The opening portion K may also penetrate through the fourth insulating layer 85 and the third insulating layer 84 in sequence and expose the first electrode 41 located in the first conductive layer 81.

Embodiments of the arrangement of the back electrodes 5 will be described below.

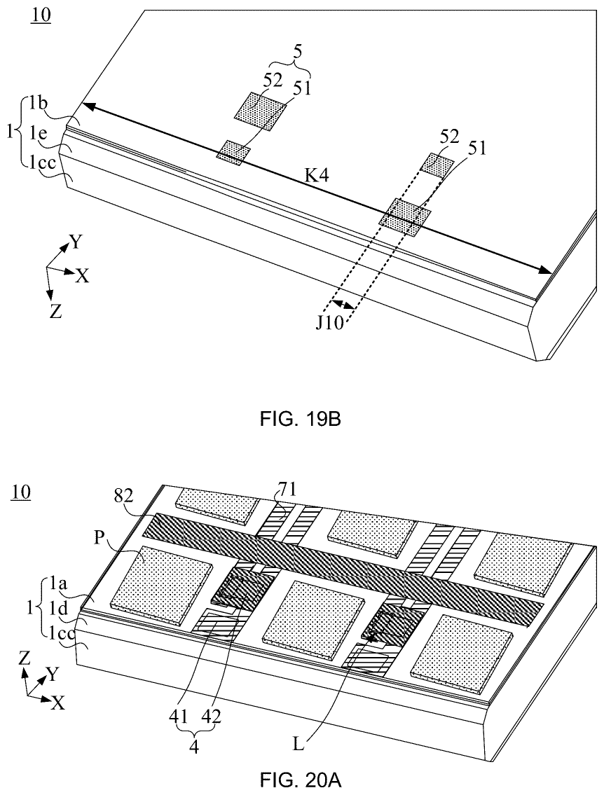

In some embodiments, as shown in FIGS. 19A and 19B, FIGS. 19A and 19B are both a diagram showing a structure of a partial region of the display panel 10, in accordance with some embodiments of the present disclosure. The plurality of back electrodes 5 are arranged at intervals in the first direction X and the second direction Y. Compared with the case where the plurality of back electrodes 5 are arranged at intervals only in the first direction X, by arranging the plurality of back electrodes 5 at intervals in the first direction X and the second direction Y, it is possible to reduce the restriction of a dimension K4 of the second surface 1b of the substrate 1 in the first direction X on the arrangement of the plurality of back electrodes 5, so as to ensure the sizes of the back electrodes 5, increase the overlapping area between the connection lead 2 and the back electrode 5, avoid poor overlapping between the connection lead 2 and the back electrode 5. As a result, it is conducive to improving the conductive performance of the connection lead 2 and the back electrode 5, thereby ensuring the normal display of the display panel 10.

For example, with continued reference to FIGS. 19A and 19B, the plurality of back electrodes 5 include a third electrode 51 and a fourth electrode 52, and the third electrode 51 and the fourth electrode 52 are disposed adjacent to each other. It may be understood that the plurality of back electrodes 5 may also include a plurality of third electrodes 51 and a plurality of fourth electrodes 52. The third electrodes 51 are arranged at intervals in the first direction X. The fourth electrodes 52 are also arranged at intervals in the first direction X, and the third electrodes 51 and the fourth electrodes 52 are arranged alternately in the second direction Y.

It will be noted that, FIGS. 19A and 19B illustrate an example in which one third electrode 51 and one fourth electrode 52 are alternately arranged in the second direction Y. However, the arrangement of the third electrodes 51 and the fourth electrodes 52 in the present disclosure is not limited to this. For example, a plurality of third electrodes 51 and a plurality of fourth electrodes 52 may also be alternately arranged in the second direction Y.

For example, with continued reference to FIGS. 19A and 19B, the third electrode 51 is closer to the selected side surface 1cc of the substrate 1 than the fourth electrode 52.

For example, as shown in FIG. 19A, the sizes of the third electrodes 51 and the fourth electrodes 52 may be same. Alternatively, as shown in FIG. 19B, the sizes of the third electrodes 51 may also be different from the sizes of the fourth electrodes 52, and the sizes of the third electrodes 51 and the fourth electrodes 52 may be designed based on actual requirements.

For example, with continued reference to FIGS. 19A and 19B, there is at least a partial overlapping region between the third electrode 51 and the fourth electrode 52 in the second direction Y.

For example, as shown in FIG. 19A, the third electrode 51 and the fourth electrode 52 may be arranged in a staggered manner in the second direction Y, and the third electrode 51 and the fourth electrode 52 partially overlap with each other in the second direction Y and have an overlapping region J9 therebetween.

For another example, as shown in FIG. 19A, the third electrode 51 and the fourth electrode 52 may be arranged in an array in the second direction Y, and the size of the third electrode 51 is the same as the size of the fourth electrode 52. The third electrode 51 and the fourth electrode 52 completely overlap with each other in the second direction Y and have an overlapping region J8 therebetween.

For yet another example, as shown in FIG. 19B, the third electrode 51 and the fourth electrode 52 may be arranged in an array in the second direction Y, and the size of the third electrode 51 is different from the size of the fourth electrode 52. One of the third electrode 51 and the fourth electrode 52 may completely overlap with the other of the third electrode 51 and the fourth electrode 52 in the second direction Y and there is an overlapping region J10.

In some embodiments, the plurality of back electrodes 5 (third electrodes 51 and fourth electrodes 52) may be disposed in a conductive layer located on the second surface 1b of the substrate 1.

As shown in FIG. 16, FIG. 16 is a sectional view of the display panel 10 in FIG. 15A taken along the section line G-G. The second surface 1b of the substrate 1 includes a third conductive layer 91, a fifth insulating layer 93, a fourth conductive layer 92, and a sixth insulating layer 94 are stacked in sequence. The third conductive layer 91 is closer to the second surface 1b of the substrate 1 than the fourth conductive layer 92.

For example, the third conductive layer 91 and the fourth conductive layer 92 may both be obtained by depositing one or more metal materials such as molybdenum (MO), titanium (Ti), aluminum (Al), copper (Cu), and indium tin oxide (ITO) through a physical vapor deposition (PVD) process.

For example, the third conductive layer 91 or the fourth conductive layer 92 may be obtained by depositing molybdenum/aluminum/molybdenum (MO/Al/MO), molybdenum/copper/molybdenum (MO/Cu/MO), titanium/copper/titanium (Ti/Cu/Ti) or indium tin oxide/copper (ITO/Cu) through a physical vapor deposition (PVD) process. The oxidation resistance capability of the fourth conductive layer 92 is greater than that of the third conductive layer 91.

In some embodiments, as shown in FIG. 17, FIG. 17 is a sectional view of the display panel 10 in FIG. 15A taken along the section line G-G. The third electrode 51 may be disposed in the same layer as the fourth electrode 52.

For example, the third electrode 51 and the fourth electrode 52 are both located in the third conductive layer 91.

In some other embodiments, with continued reference to FIG. 16, the third electrode 51 and the fourth electrode 52 may be disposed in different layers, and the third electrode 51 is closer to the second surface 1b of the substrate 1 than the fourth electrode 52.

By arranging the third electrode 51 and the fourth electrode 52 in different conductive layers (the third conductive layer 91 and the fourth conductive layer 92), the plurality of back electrodes 5 are located in different planes, and the arrangement of the plurality of back electrodes 5 (the third electrode 51 and the fourth electrode 52) is changed from a plane arrangement to a three-dimensional arrangement. That is to say, the plurality of back electrodes 5 may not only be arranged at intervals in the first direction X and the second direction Y, but also may be arranged at intervals in the third direction Z, so that the restriction of the plane space on the arrangement of the back electrodes 5 (the third electrode 51 and the fourth electrode 52) may be reduced, the sizes of the back electrodes 5 may be ensured, the overlapping area between the connection lead 2 and the back electrode 5 may be further increased, poor overlapping between the connection lead 2 and the back electrode 5 may be avoided. As a result, it is conducive to further improving the conductive performance of the connection lead 2 and the back electrode 5, thereby ensuring the normal display of the display panel 10.

For example, in addition to the conductive layer for providing the third electrodes 51 and the conductive layer for providing the fourth electrodes 52, other conductive layers for providing the back electrodes 5 may also be formed. The conductive layer for providing the third electrodes 51, the conductive layer for providing the fourth electrodes 52, and other conductive layers for providing the back electrodes 5 may be stacked in the third direction Z. The restriction of the plane space on the arrangement of the back electrodes 5 may be further reduced, the sizes of the back electrodes 5 may be ensured, and the overlapping area between the connection lead 2 and the back electrode 5 may be further increased, and poor overlapping between the connection lead 2 and the back electrode 5 may be avoided. As a result, it is conducive to further improving the conductive performance of the connection lead 2 and the back electrode 5, thereby ensuring the normal display of the display panel 10.

For example, the third electrodes 51 may be located on the third conductive layer 91, and the fourth electrodes 52 may be located on the fourth conductive layer 92.

For example, with continued reference to FIG. 16, an orthogonal projection of the third electrode 51 on the second surface 1b of the substrate 1 does not overlap with an orthogonal projection of the fourth electrode 52 on the second surface 1b of the substrate 1. That is to say, there is no overlapping region between the orthogonal projection of the third electrode 51 on the second surface 1b of the substrate 1 and the orthogonal projection of the fourth electrode 52 on the second surface 1b of the substrate 1.

Alternatively, as shown in FIG. 18, FIG. 18 is a sectional view of the display panel 10, in accordance with some embodiments of the present disclosure. The orthogonal projection of the third electrode 51 on the second surface 1b of the substrate 1 partially overlaps with the orthogonal projection of the fourth electrode 52 on the second surface 1b of the substrate 1. That is to say, there is an overlapping region J5 between the orthogonal projection of the third electrode 51 on the second surface 1b of the substrate 1 and the orthogonal projection of the fourth electrode 52 on the second surface 1b of the substrate 1.

In some embodiments, with continued reference to FIGS. 16, 17 and 18, the opening portions K may also be used to expose the plurality of back electrodes 5 (the third electrode 51 and the fourth electrode 52).

For example, as shown in FIG. 17, the opening portions K may penetrate through the fifth insulating layer 93 and expose the third electrode 51 and the fourth electrode 52 located in the third conductive layer 91.

Alternatively, as shown in FIGS. 16 and 18, the opening portion K may penetrate through the sixth insulating layer 94 and expose the fourth electrode 52 located in the fourth conductive layer 92. The opening portion K may also penetrate through the sixth insulating layer 94 and the fifth insulating layer 93 in sequence and expose the third electrode 51 located in the third conductive layer 91.

In some embodiments, with continued reference to FIGS. 9A and 9B, the first connection lead 21 may be used to connect the first electrode 41 and the third electrode 51.

With continued reference to FIGS. 10A and 10B, the second connection lead 22 may be used to connect the second electrode 42 and the fourth electrode 52.

For example, the plurality of front electrodes 4 (i.e., the first electrodes 41 and the second electrodes 42) and the plurality of back electrodes 5 (i.e., the third electrodes 51 and the fourth electrodes 52) each may have a gold surface. In a case where the material of the connection leads 2 (i.e., the first connection lead 21 and the second connection lead 22) includes silver (Ag), gold (Au) has a good bonding performance with silver (Ag), which may reduce the contact resistance between the front electrode 4 and the connection lead 2 and the contact resistance between the back electrode 5 and the connection lead 2.

For example, the first electrode 41 and the third electrode 51 are disposed correspondingly, and the orthogonal projections of the first electrode 41 and the third electrode 51 on the second surface 1b of the substrate 1 at least partially overlap with each other. For example, the orthogonal projections of the first electrode 41 and the third electrode 51 on the second surface 1b of the substrate 1 may partially overlap with each other; alternatively, as shown in FIG. 16, the orthogonal projections of the first electrode 41 and the third electrode 51 on the second surface 1b of the substrate 1 may completely overlap with each other and have an overlapping region J6 therebetween.

The second electrode 42 and the fourth electrode 52 are disposed correspondingly, and the orthogonal projections of the second electrode 42 and the fourth electrode 52 on the second surface 1b of the substrate 1 at least partially overlap with each other. For example, the orthogonal projections of the second electrode 42 and the fourth electrode 52 on the second surface 1b of the substrate 1 may partially overlap with each other; alternatively, as shown in FIG. 16, the orthogonal projections of the second electrode 42 and the fourth electrode 52 on the second surface 1b of the substrate 1 may completely overlap with each other and have an overlapping region J7 therebetween.

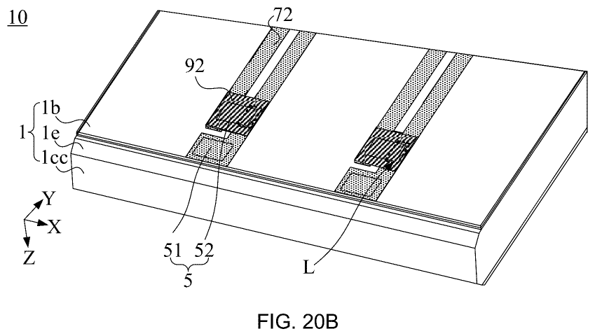

In some embodiments, as shown in FIG. 20A and in combination with FIG. 16, FIG. 20A is a diagram showing a structure of a partial region of the display panel 10, in accordance with some embodiments of the present disclosure. The display panel 10 further includes a plurality of first signal lines 71, and the plurality of first signal lines 71 are located on the first surface 1a of substrate 1. An end of one of the plurality of first signal lines 71 is connected to one front electrode 4 (the first electrode 41 or the second electrode 42) located on the first surface 1a of the substrate 1, and another end of one of the plurality of first signal lines 71 is connected to the pixel unit P located on the first surface 1a of the substrate 1, and the first signal line 71 is used to transmit signals to the pixel unit P to control the pixel unit P to emit light.

For example, the first signal lines 71 may be located in the first conductive layer 81, or the first signal lines 71 may also be located in the second conductive layer 82.

In a case where the first electrode 41 and the second electrode 42 in the front electrodes 4 are disposed in different layers, that is, one of the first electrode 41 and the second electrode 42 is located in the first conductive layer 81, and the other of the first electrode 41 and the second electrode 42 is located in the second conductive layer 82, one of the first electrode 41 and the second electrode 42 that is disposed in the same layer as the first signal line 71 may be directly connected to the first signal line 71, and the other of the first electrode 41 and the second electrode 42 may be connected to the first signal line 71 through the via hole L.

For example, as shown in FIG. 20A and in combination with FIG. 16, the first electrode 41 is located in the first conductive layer 81, the second electrode 42 is located in the second conductive layer 82, and the first signal line 71 is located in the first conductive layer 81. That is to say, the first electrode 41 and the first signal line 71 are disposed in a same layer, and the second electrode 42 and the first signal line 71 are disposed in different layers. The first electrode 41 is directly connected to the first signal line 71, and the second electrode 42 is connected to the first signal line 71 through the via hole L.

In some embodiments, as shown in FIG. 20B, FIG. 20B is a diagram showing a structure of a partial region of the display panel 10, in accordance with some embodiments of the present disclosure. The display panel 10 further includes a plurality of second signal lines 72, and the plurality of second signal lines 72 are located on the second surface 1b of substrate 1. An end of one of the plurality of second signal lines 72 is connected to one back electrode 5 (the third electrode 51 or the fourth electrode 52) located on the second surface 1b of the substrate 1, and another end of one of the plurality of second signal lines 72 is connected to the circuit board (not shown in the drawing), and the second signal line 72 is used to transmit control signals output by the circuit board.

For example, the second signal lines 72 may be located in the third conductive layer 91, or the second signal lines 72 may also be located in the fourth conductive layer 92.

In a case where the third electrode 51 and the fourth electrode 52 in the back electrodes 5 are disposed in different layers, that is, one of the third electrode 51 and the fourth electrode 52 is located in the third conductive layer 91, and the other of the third electrode 51 and the fourth electrode 52 is located in the fourth conductive layer 92, one of the third electrode 51 and the fourth electrode 52 that is disposed in the same layer as the second signal line 72 may be directly connected to the second signal line 72, and the other of the third electrode 51 and the fourth electrode 52 may be connected to the second signal line 72 through the via hole L.

For example, as shown in FIG. 20B and in combination with FIG. 16, the third electrode 51 is located in the third conductive layer 91, the fourth electrode 52 is located in the fourth conductive layer 92, and the second signal line 72 is located in the third conductive layer 91. That is to say, the third electrode 51 and the second signal line 72 are disposed in a same layer, and the fourth electrode 52 and the second signal line 72 are disposed in different layers. The third electrode 51 is directly connected to the second signal line 72, and the fourth electrode 52 is connected to the second signal line 72 through the via hole L.

In some embodiments, the pixel unit may be a light-emitting unit, and the light-emitting unit may include a light-emitting diode (LED). In this case, the display panel 10 may be considered as a light-emitting panel. The embodiments of the display panel 10 described in the present disclosure, including but not limited to the arrangement of the connection leads 2, the arrangement of the front electrodes 4 and the arrangement of the back electrodes 5, the positional relationships between the connection leads 2 and the pixel units P and between the front electrodes 4 and the pixel units P, the arrangement of the depressed regions Q, may be applied individually or in full to the light-emitting panel.

For example, the light-emitting panel may be used as a backlight source.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a substrate including a first surface and a second surface that are oppositely disposed, and at least one side surface connecting the first surface and the second surface, at least one of the at least one side surface being a selected side surface; and
a plurality of connection leads, each connection lead in the plurality of connection leads extending from the first surface to the second surface through the selected side surface;
wherein the plurality of connection leads include a first connection lead and a second connection lead, and the first connection lead and the second connection lead are adjacent to each other and disposed in different layers in a direction perpendicular to the surface of the substrate.

2. The display panel according to claim 1, wherein orthogonal projections of the first connection lead and the second connection lead on the substrate at least partially overlap with each other.

3. The display panel according to claim 1, wherein line widths of the first connection lead and the second connection lead are different.

4. The display panel according to claim 1, wherein signals transmitted by the first connection lead are different from signals transmitted by the second connection lead.

5. The display panel according to claim 1, wherein one of the first connection lead and the second connection lead is in contact with the surface of the substrate.

6. The display panel according to claim 1, wherein the display panel further comprises:
a plurality of front electrodes disposed on a side of the first surface of the substrate;
the plurality of front electrodes including a first electrode and a second electrode, and the first electrode and the second electrode being disposed adjacent to each other; and
a plurality of back electrodes disposed on a side of the second surface of the substrate; the plurality of back electrodes including a third electrode and a fourth electrode, and the third electrode and the fourth electrode being disposed adjacent to each other;
wherein the first connection lead connects the first electrode and the third electrode;
the second connection lead connects the second electrode and the fourth electrode; and
orthogonal projections of the first electrode and the third electrode on the second surface at least partially overlap with each other, and orthogonal projections of the second electrode and the fourth electrode on the second surface at least partially overlap with each other.

7. The display panel according to claim 6, wherein the first electrode is disposed in a same layer as the second electrode, and/or, the third electrode is disposed in a same layer as the fourth electrode.

8. The display panel according to claim 7, wherein one of the first connection lead and the second connection lead is directly connected to at least one of the plurality of front electrodes and at least one of the plurality of back electrodes, and another of the first connection lead and the second connection lead is connected to one or more of the plurality of front electrodes and one or more of the plurality of back electrodes through a via hole.

9. The display panel according to claim 6, wherein the first electrode and the second electrode are disposed in different layers, and the first electrode is closer to the first surface than the second electrode;
and/or, the third electrode and the fourth electrode are disposed in different layers, and the third electrode is closer to the second surface than the fourth electrode.

10. The display panel according to claim 9, wherein the first connection lead is closer to the substrate than the second connection lead.

11. The display panel according to claim 9, wherein an orthogonal projection of the first electrode on the first surface at least partially overlaps with an orthogonal projection of the second electrode on the first surface;
and/or, the orthogonal projection of the third electrode on the second surface at least partially overlaps with the orthogonal projection of the fourth electrode on the second surface.

12. The display panel according to claim 6, wherein the display panel further comprises a plurality of pixel units located on the first surface; and
the plurality of pixel units include two pixel units that are adjacent to each other in a first direction and both proximate to the selected side surface, and the first electrode and the second electrode are disposed between the two pixel units.

13. The display panel according to claim 1, wherein the display panel further comprises a plurality of pixel units located on the first surface; and
the plurality of pixel units include two pixel units that are adjacent to each other in a first direction and both proximate to the selected side surface, and the first connection lead and the second connection lead are disposed between the two pixel units.

14. The display panel according to claim 6, wherein the display panel further comprises a plurality of pixel units located on the first surface;
the plurality of pixel units include two pixel units that are adjacent to each other in a first direction and both proximate to the selected side surface, and the first electrode and the second electrode at least partially overlap with the two pixel units in a second direction; and
the second direction is perpendicular to the first direction.

15. The display panel according to claim 1, wherein the display panel further comprises a first insulating layer; and
the first insulating layer is located between the first connection lead and the second connection lead.

16. The display panel according to claim 1, wherein the display panel further comprises at least one depressed region located on at least the selected side surface of the substrate; and
an orthogonal projection of one of the first connection lead and the second connection lead that is closer to the substrate on the selected side surface is located within the depressed region.

17. The display panel according to claim 16, wherein a ratio of a dimension of the depressed region in a first direction to a dimension of the first connection lead in the first direction is within a range of 1 to 2, inclusive.

18. The display panel according to claim 6, wherein the display panel further comprises a protective layer; the protective layer covers at least the second connection lead, and at least one of the plurality of front electrodes and at least one of the plurality of back electrodes that are connected to the second connection lead.

19. A display apparatus, comprising:
the display panel according to claim 1; and
a circuit board electrically connected to the display panel; the circuit board being configured to drive the display panel to display images.

20. A tiled display apparatus, comprising a plurality of display panels each according to claim I and at least one circuit board;
wherein the plurality of the display panels are tiled together, and each of the at least one circuit board is electrically connected to at least one of the plurality of display panels.
